(19) United States
(12) Patent Application Publication
(10) Pub. No.: US 2023/0128161 A1
(43) Pub. Date: Apr. 27, 2023

(54) DISPLAY DEVICE AND MANUFACTURING METHOD THEREFOR

(71) Applicant: Samsung Display Co., LTD., Yongin-si, Gyeonggi-do (KR)

(72) Inventors: Myeong Hun SONG, Daegu (KR); Sung Jin LEE, Yongin-si, Gyeonggi-do (KR); Jong Chan LEE, Suwon-si Gyeonggi-do (KR); Tae Hee LEE, Asan-si, Chungcheongnam-do (KR); Hyun Wook LEE, Suwon-si, Gyeonggi-do (KR); Seung Jin CHU, Gwangmyeong-si, Gyeonggi-do (KR)

(73) Assignee: Samsung Display Co., LTD., Yongin-si, Gyeonggi-do (KR)

(21) Appl. No.: 17/915,276

(22) PCT Filed: Jun. 10, 2020
(86) PCT No.: PCT/KR2020/007483

§ 371 Date: Sep. 28, 2022

(30) Foreign Application Priority Data
Apr. 6, 2020 (KR) 10-2020-0041587

(51) Int. Cl. H01L 33/38; H01L 33/62; H01L 27/15; H01L 33/00

(52) U.S. Cl. CPC H01L 33/387; H01L 33/62; H01L 27/156; H01L 33/005; H01L 2933/0016; H01L 2933/0066

(57) ABSTRACT

A display device includes a first electrode and a second electrode spaced apart from each other on a substrate; a first insulating layer disposed between the first electrode and the second electrode, and not overlapping the first electrode and the second electrode in a thickness direction of the first insulating layer; and a light emitting element disposed on the first insulating layer, wherein side surfaces of the first insulating layer contact the first electrode and the second electrode.

### CROSS-REFERENCE TO RELATED APPLICATION

This application is a national entry of International Application No. PCT/KR2020/007483, filed on Jun. 10, 2020, which claims under 35 U.S.C. §§ 119(a) and 365(b) priority to and benefits of Korean Patent Application No. 10-2020-0041587, filed on Apr. 6, 2020, in the Korean Intellectual Property Office (KIPO), the entire contents of which are incorporated herein by reference.

### BACKGROUND

### 1. Technical Field

The disclosure relates to a display device and a manufacturing method therefor.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

### SUMMARY

Aspects of the disclosure provide a display device in which alignment of light emitting elements is improved (or misalignment thereof is reduced) by reducing process dispersion of a distance between electrodes on which the light emitting elements are disposed.

Aspects of the disclosure also provide a method of manufacturing a display device, in which a short circuit between electrodes due to a residual layer resulting from poor etching is prevented when the electrodes are formed, and process conditions for a gap between the electrodes can be easily secured.

It should be noted that aspects of the disclosure are not limited thereto and other aspects, which are not mentioned herein, will be apparent to those of ordinary skill in the art from the following description.

According to an embodiment of the disclosure, a display device comprises a first electrode and a second electrode spaced apart from each other on a substrate, a first insulating layer disposed between the first electrode and the second electrode and not overlapping the first electrode and the second electrode in a thickness direction of the first insulating layer, and a light emitting element disposed on the first insulating layer, wherein side surfaces of the first insulating layer contact the first electrode and the second electrode.

A first portion of each of the first electrode and the second electrode which contact the side surfaces of the first insulating layer respectively may contact the side surfaces of the first insulating layer in the thickness direction of the first insulating layer.

A thickness of the first insulating layer may be greater than a maximum thickness of each of the first electrode and the second electrode.

A width of the first portion of each of the first electrode and the second electrode may be smaller than a thickness of portions other than the first portion.

An upper surface of the first portion of each of the first and second electrode and an upper surface of the first insulating layer may lie in a same plane, and respective ends of the light emitting element may electrically contact the first portion of each of the first electrode and the second electrode.

A height of a contact surface between each of the first electrode and the second electrode and a side surface of the first insulating layer may be greater than a thickness of each of the first electrode and the second electrode.

The light emitting element may extend in a direction, and a length of the light emitting element may be greater than a width of the first insulating layer.

An end of the light emitting element may be disposed on the first electrode, and another end of the light emitting element may be disposed on the second electrode.

The display device may further comprise a second insulating layer including at least a portion disposed on the light emitting element, wherein a width of the second insulating layer may be smaller than the width of the first insulating layer.

The display device may further comprise a first contact electrode disposed on the first electrode and electrically contacting an end of the light emitting element, and a second contact electrode disposed on the second electrode and electrically contacting another end of the light emitting element.

The display device may further comprise banks disposed between the substrate and the first electrode and between the substrate and the second electrode, wherein the first insulating layer may do not contact the banks.

According to an embodiment of the disclosure, a display device comprises a first electrode disposed on a substrate and extending in a first direction, a second electrode spaced apart from the first electrode in a second direction and extending in the first direction, an insulating layer disposed between the first electrode and the second electrode and extending in the first direction, and light emitting elements disposed on the insulating layer and arranged in the first direction. Side surfaces of the first insulating layer contact the first electrode and the second electrode, and an end of each of the light emitting elements is disposed on the first electrode, and another end of each of the light emitting elements is disposed on the second electrode.

The display device may further comprise a first contact electrode disposed on the first electrode and electrically contacting the end of each of the light emitting elements, and a second contact electrode disposed on the second electrode and electrically contacting another end of each of the light emitting elements. At least a portion of each of the first contact electrode and the second contact electrode may overlap the insulating layer in a thickness direction of the insulating layer.

The first electrode may comprise a bent portion extending in the second direction different from the first direction, a widened portion extending in the first direction and having a greater width than the bent portion and a connection portion extending between the bent portion and the widened portion and extending in the first direction, and the insulating layer may be disposed between the widened portion of the first electrode and the second electrode so that a side surface of the insulating layer contacts the widened portion of the first electrode.

The second electrode may have a symmetrical structure to the electrode with respect to the first insulating layer, and another side surface of the insulating layer may contact a widened portion of the second electrode.

A distance between the widened portion of the first electrode and the widened portion of the second electrode may be smaller than a distance between the connection portion of the first electrode and a connection portion of the second electrode, and a shortest distance between the bent portion of the first electrode and a bent portion of the second electrode may be greater than the distance between the widened portion of the first electrode and the widened portion of the second electrode and smaller than the distance between the connection portion of the first electrode and the connection portion of the second electrode.

According to an embodiment of the disclosure, a method of manufacturing a display device, the method comprises forming an insulating layer on a substrate and forming an electrode layer covering the substrate and the insulating layer, forming a first electrode and a second electrode spaced apart from each other by the insulating layer by partially removing the electrode layer to expose an upper surface of the insulating layer, and placing light emitting elements on the insulating layer.

The removing of the electrode layer may comprise a first etching process performed as a wet etching process and a second etching process performed as a dry etching process after the first etching process.

The method may comprise forming of banks spaced apart from each other on the substrate before the forming of the insulating layer.

The forming of the electrode layer may comprise forming the electrode layer to cover the banks and the insulating layer, and the forming of the first electrode and the second electrode may comprise disposing the first and second electrodes on the banks and directly disposing at least a portion of each of the first electrode and the second electrode on the substrate.

The details of other embodiments are included in the detailed description and the accompanying drawings.

In a display device according to an embodiment, an insulating layer is disposed between a plurality of electrodes, and light emitting elements are disposed on the insulating layer. The insulating layer may secure a space in which the light emitting elements are disposed while preventing a distance between the electrodes from deviating from a design value. Accordingly, in the display device, the light emitting elements are horizontally disposed on the insulating layer and the electrodes, thereby preventing poor contact with contact electrodes.

In addition, in a method of manufacturing the display device, the insulating layer is formed before the electrodes. Therefore, it is possible to prevent a short circuit caused by a residual layer and a defect in the profile of an etched cross section that may occur in an electrode formation process.

The effects according to the embodiments are not limited by the contents exemplified above, and more various effects are included in this disclosure.

### BRIEF DESCRIPTION OF THE DRAWINGS

FIG. 1 is a schematic plan view of a display device according to an embodiment;

FIG. 2 is a schematic plan view of a pixel of the display device according to the embodiment;

FIG. 3 is a schematic cross-sectional view taken along lines Q1-Q1′, Q2-Q2′ and Q3-Q3′ of FIG. 2;

FIG. 4 is a schematic enlarged view of portion QA of FIG. 3;

FIG. 5 is a schematic partial cross-sectional view of a display device according to another embodiment;

FIG. 6 is a schematic view of a light emitting element according to an embodiment;

FIG. 7 is a flowchart illustrating a process of manufacturing a display device according to an embodiment;

FIGS. 8 through 17 are schematic cross-sectional views illustrating a process of manufacturing a display device according to an embodiment;

FIG. 18 is a schematic cross-sectional view of a portion of a display device according to another embodiment;

FIG. 19 is a schematic plan view of a subpixel of a display device according to another embodiment;

FIG. 20 is a schematic plan view of a subpixel of a display device according to another embodiment; and

FIG. 21 is a schematic cross-sectional view taken along line QB-QB′ of FIG. 20.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will more fully convey the scope of the disclosure to those skilled in the art.

It will also be understood that when a layer is referred to as being “on” another layer or substrate, it can be directly on the other layer or substrate, or intervening layers may also be present. Further, in the specification, the word “on” or “above” means positioned on or below the object portion, and does not necessarily mean positioned on the upper side of the object portion based on a gravitational direction. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within 30%, 20%, 10%, 5% of the stated value.

The term “and/or” includes all combinations of one or more of which associated configurations may define. For example, “A and/or B” may be understood to mean “A, B, or A and B.”

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

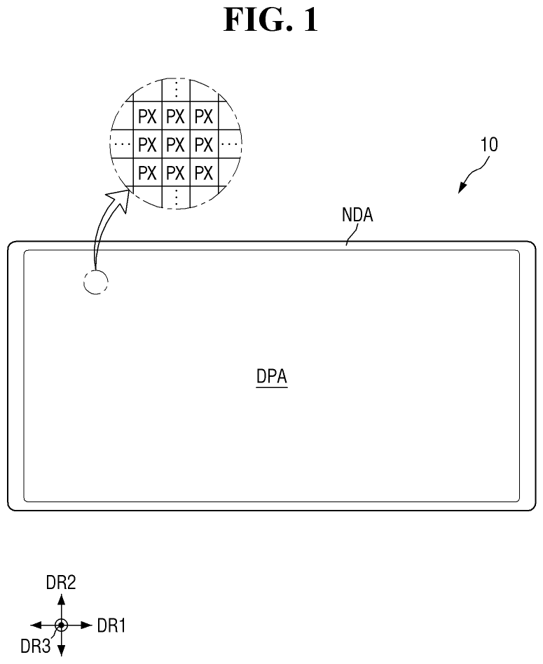

FIG. 1 is a schematic plan view of a display device according to an embodiment.

In the specification, “above,” “top” and “upper surface” refer to an upward direction of a display device 10, for example, a direction in a third direction DR3, and “below,” “bottom,” and “lower surface” refer to the other direction in the third direction DR3. In addition, “left,” “right,” “up,” and “down” refer to directions when the display device 10 is seen in a plan view. For example, “left” refers to a direction in a first direction DR1, “right” refers to the other direction in the first direction DR1, “up” refers to a direction in a second direction DR2, and “down” refers to the other direction in the second direction DR2.

Referring to FIG. 1, the display device 10 displays moving images or still images. The display device 10 may refer to any electronic device that provides a display screen. Examples of the display device 10 may include televisions, laptop computers, monitors, billboards, Internet of things (IoT) devices, mobile phones, smartphones, tablet personal computers (PCs), electronic watches, smartwatches, watch phones, head-mounted displays, mobile communication terminals, electronic notebooks, electronic-book readers, portable multimedia players (PMPs), navigation devices, game consoles, and digital cameras and camcorders, all of which provide a display screen.

The display device 10 includes a display panel that provides a display screen. Examples of the display panel may include inorganic light-emitting diode (LED) display panels, organic light emitting display panels, quantum dot light emitting display panels, plasma display panels, and field emission display panels. A case where an inorganic LED display panel is applied as an example of the display panel will be described below, but the disclosure is not limited to this case, and other display panels can also be applied as long as the same technical spirit is applicable.

The shape of the display device 10 can be variously modified. For example, the display device 10 may have various shapes such as a horizontally long rectangle, a vertically long rectangle, a square, a quadrilateral with rounded corners (vertices), other polygons, and a circle. The shape of a display area DPA of the display device 10 may also be similar to the overall shape of the display device 10. FIG. 1 illustrates the display device 10 and the display area DPA having a horizontally long rectangular shape.

The display device 10 may include the display area DPA and a non-display area NDA. The display area DPA is an area where an image can be displayed, and the non-display area NDA is an area where no image is displayed. The display area DPA may also be referred to as an active area, and the non-display area NDA may also be referred to as an inactive area. The display area DPA may generally occupy a center of the display device 10.

The display area DPA may include pixels PX. The pixels PX may be arranged in a matrix direction. Each of the pixels PX may be rectangular or square in a plan view. However, the disclosure is not limited thereto, and each of the pixels PX may also have a rhombic shape having each side inclined with respect to a direction. The pixels PX may be alternately arranged in a stripe type or a PenTile® type. Each of the pixels PX may include one or more light emitting elements 30 which emit light of a specific wavelength band to display a specific color.

The non-display area NDA may be disposed around the display area DPA. The non-display area NDA may entirely or partially surround the display area DPA. The display area DPA may be rectangular, and the non-display area NDA may be disposed adjacent to four sides of the display area DPA. The non-display area NDA may form a bezel of the display device 10. In each non-display area NDA, wirings or circuit drivers included in the display device 10 may be disposed, or external devices may be mounted.

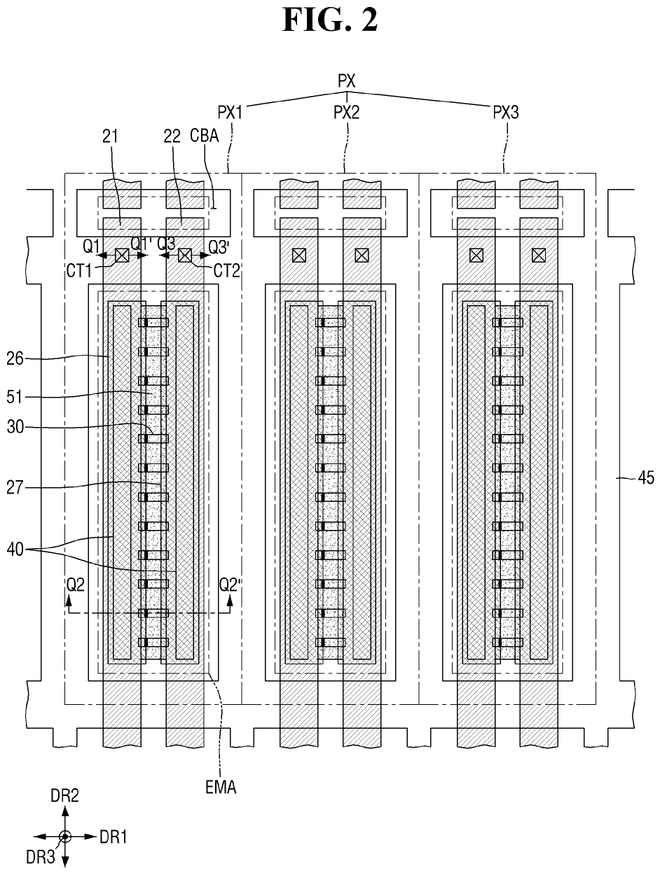

FIG. 2 is a schematic plan view of a pixel of the display device according to the embodiment.

Referring to FIG. 2, each of the pixels PX may include subpixels PXn (where n is an integer of 1 to 3). For example, a pixel PX may include a first subpixel PX1, a second subpixel PX2, and a third subpixel PX3. The first subpixel PX1 may emit light of a first color, the second subpixel PX2 may emit light of a second color, and the third subpixel PX3 may emit light of a third color. The first color may be blue, the second color may be green, and the third color may be red. However, the disclosure is not limited thereto, and the subpixels PXn may also emit light of a same color. Although FIG. 2 illustrates that a pixel PX includes three subpixels PXn, the disclosure is not limited thereto, and the pixel PX may also include more subpixels PXn.

Each subpixel PXn of the display device 10 may include an emission area EMA and a non-emission area. The emission area EMA may be an area in which the light emitting elements 30 are disposed to emit light of a specific wavelength band. The non-emission area may be an area in which the light emitting elements 30 are not disposed and from which no light is output because light emitted from the light emitting elements 30 does not reach this area. An active layer 36 of each light emitting element 30 may emit light in any suitable direction, and the light may be radiated toward sides of the light emitting element 30. The emission area may include an area where the light emitting elements 30 are located and where light emitted from the light emitting elements 30 is output to an area adjacent to the light emitting elements 30.

However, the disclosure is not limited thereto, and the emission area may also include an area where light emitted from the light emitting elements 30 is output after being reflected or refracted by other members. Light emitting elements 30 may be disposed in each subpixel PXn, and an area where the light emitting elements 30 are located and an area adjacent to this area may form the emission area.

Each subpixel PXn may include a cutout area CBA disposed in the non-emission area. The cutout area CBA may be disposed on a side of the emission area EMA in the second direction DR2. The cutout area CBA may be disposed between the emission areas EMA of subpixels PXn neighboring each other in the second direction DR2. Emission areas EMA and cutout areas CBA may be arranged in the display area DPA of the display device 10. For example, the emission areas EMA and the cutout areas CBA may each be repeatedly arranged in the first direction DR1, but may be alternately arranged in the second direction DR2. A distance between the cutout areas CBA in the first direction DR1 may be smaller than a distance between the emission areas EMA in the first direction DR1. As will be described below, a second bank 45 may be disposed between the cutout areas CBA and the emission areas EMA, and a distance between the cutout areas CBA and the emission areas EMA may vary according to a width of the second bank 45. Since the light emitting elements 30 are not disposed in the cutout areas CBA, no light is emitted from the cutout areas CBA. However, portions of electrodes 21 and 22 disposed in each subpixel PXn may be disposed in the cutout area CBA. The electrodes 21 and 22 disposed in each subpixel PXn may be separated from those of an adjacent subpixel PXn in the cutout area CBA. This will be described in more detail below.

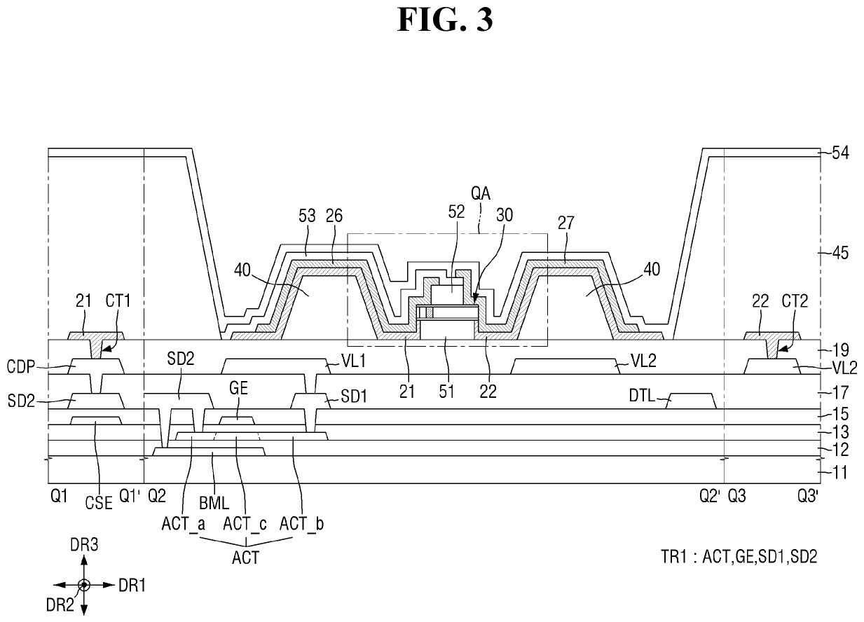

FIG. 3 is a schematic cross-sectional view taken along lines Q1-Q1′, Q2-Q2′, and Q3-Q3′ of FIG. 2. FIG. 3 illustrates a cross section of only the first subpixel PX1 of FIG. 3, but the same illustration may apply to other pixels PX or subpixels PXn. FIG. 3 illustrates a cross section across an end and another end of a light emitting element 30 in the first subpixel PX1.

Referring to FIG. 3 in connection with FIG. 2, the display device 10 may include a first substrate 11 and a semiconductor layer, conductive layers, and insulating layers disposed on the first substrate 11.

The first substrate 11 may be an insulating substrate. The first substrate 11 may be made of an insulating material such as glass, quartz, or polymer resin. The first substrate 11 may be a rigid substrate, but may also be a flexible substrate that can be bent, folded, rolled, etc.

A light blocking layer BML may be disposed on the first substrate 11. The light blocking layer BML is overlapped by an active layer (or active material layer) ACT of a first transistor TR1 of the display device 10. The light blocking layer BML may include a light blocking material to prevent incidence of light to the active layer ACT of the first transistor. For example, the light blocking layer BML may be made of an opaque metal material that blocks transmission of light. However, the disclosure is not limited thereto. In some embodiments, the light blocking layer BML may be omitted.

A buffer layer 12 may be disposed on the entire surface (or entire side) of the first substrate 11 and the light blocking layer BML. The buffer layer 12 may be formed on the first substrate 11 to protect the first transistors TR1 of each pixel PX from moisture introduced through the first substrate 11 which is vulnerable to moisture penetration and may perform a surface planarization function. The buffer layer 12 may be composed of inorganic layers stacked alternately each other. For example, the buffer layer 12 may be a multilayer in which inorganic layers including at least any one of silicon oxide (SiOₓ), silicon nitride (SiNₓ), and silicon oxynitride (SiON) are alternately stacked each other.

The semiconductor layer is disposed on the buffer layer 12. The semiconductor layer may include the active layer ACT of the first transistor TR1. The active layer ACT may be partially overlapped by a gate electrode GE of a first gate conductive layer which will be described below.

Although only the first transistor TR1 among the transistors included in each subpixel PXn of the display device 10 is illustrated in the drawings, the disclosure is not limited thereto. The display device 10 may include more transistors. For example, the display device 10 may include two or three transistors by including one or more transistors in addition to the first transistor TR1 in each subpixel PXn.

In an embodiment, the semiconductor layer may include polycrystalline silicon, monocrystalline silicon, an oxide semiconductor, or the like. The polycrystalline silicon may be formed by crystalizing amorphous silicon In case that the semiconductor layer includes polycrystalline silicon, the active layer ACT may include doped regions ACT_a and ACT_b doped with impurities and a channel region ACT_c between them.

In an embodiment, the semiconductor layer may include an oxide semiconductor. Each doped region of the active layer ACT may be a conducting region. The oxide semiconductor may be an oxide semiconductor containing indium (In). In some embodiments, the oxide semiconductor may be indium tin oxide (ITO), indium zinc oxide (IZO), indium gallium oxide (IGO), indium zinc tin oxide (IZTO), indium gallium zinc oxide (IGZO), indium gallium tin oxide (IGTO), or indium gallium zinc tin oxide (IGZTO). However, the disclosure is not limited thereto.

A first gate insulating layer 13 is disposed on the semiconductor layer and the buffer layer 12. The first gate insulating layer 13 may be disposed on the buffer layer 12 having the semiconductor layer. The first gate insulating layer 13 may function as a gate insulating film of each transistor. The first gate insulating layer 13 may be an inorganic layer including an inorganic material such as silicon oxide (SiOₓ), silicon nitride (SiNₓ), or silicon oxynitride (SiON), or may have a structure in which any of the above materials are stacked each other.

The first gate conductive layer is disposed on the first gate insulating layer 13. The first gate conductive layer may include a first gate electrode GE of the first transistor TR1 and a first capacitive electrode CSE of a storage capacitor. The first gate electrode GE may overlap the channel region ACT_c of the active layer ACT in a thickness direction. The first capacitive electrode CSE may overlap a first source/drain electrode SD1 of the first transistor TR1, which will be described below, in the thickness direction. In some embodiments, the first capacitive electrode CSE may be integrally connected to (or may be integral with) the first gate electrode GE, and an integrated layer may partially include the first gate electrode GE and the first capacitive electrode CSE. The first capacitive electrode CSE may overlap the first source/drain electrode SD1 in the thickness direction, and the storage capacitor may be formed between them.

The first gate conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof. However, the disclosure is not limited thereto.

A first protective layer 15 is disposed on the first gate conductive layer. The first protective layer 15 may cover the first gate conductive layer to protect the first gate conductive layer. The first protective layer 15 may be an inorganic layer including an inorganic material such as silicon oxide (SiOₓ), silicon nitride (SiNₓ), or silicon oxynitride (SiON), or may have a structure in which any of the above materials are stacked each other.

A first data conductive layer is disposed on the first protective layer 15. The first data conductive layer may include the first source/drain electrode SD1 and a second source/drain electrode SD2 of the first transistor TR1 and a data line DTL.

The source/drain electrodes SD1 and SD2 of the first transistor TR1 may respectively contact the doped regions ACT_a and ACT_b of the active layer ACT through contact holes penetrating a first interlayer insulating layer 17 and the first gate insulating layer 13. The second source/drain electrode SD2 of the first transistor TR1 may be electrically connected to the light blocking layer BML through another contact hole.

The data line DTL may transmit a data signal to other transistors (not illustrated) included in the display device 10. Although not illustrated in the drawings, the data line DTL may be connected to source/drain electrodes of other transistors.

The first data conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof. However, the disclosure is not limited thereto.

The first interlayer insulating layer 17 is disposed on the first data conductive layer. The first interlayer insulating layer 17 may function as an insulating film between the first data conductive layer and other layers on the first data conductive layer. The first interlayer insulating layer 17 may cover the first data conductive layer and protect the first data conductive layer. The first interlayer insulating layer 17 may be an inorganic layer including an inorganic material such as silicon oxide (SiOₓ), silicon nitride (SiNₓ), or silicon oxynitride (SiON), or may have a structure in which any of the above materials are stacked each other.

A second data conductive layer is disposed on the first interlayer insulating layer 17. The second data conductive layer may include a first voltage wiring VL1, a second voltage wiring VL2, and a first conductive pattern CDP. A high-potential voltage (or a first power supply voltage) supplied to the first transistor TR1 may be applied to the first voltage wiring VL1, and a low-potential voltage (or a second power supply voltage) supplied to a second electrode 22 may be applied to the second voltage wiring VL2. An alignment signal needed to align the light emitting elements 30 may be transmitted to the second voltage wiring VL2 during a manufacturing process of the display device 10.

The first conductive pattern CDP may be electrically connected to the second source/drain electrode SD2 of the first transistor TR1 through a contact hole formed in the first interlayer insulating layer 17. The first conductive pattern CDP may also contact a first electrode 21 which will be described below, and the first transistor TR1 may transfer the first power supply voltage, received from the first voltage wiring VL1, to the first electrode 21 through the first conductive pattern CDP. Although it is illustrated in the drawings that the second data conductive layer includes a second voltage wiring VL2 and a first voltage wiring VL1, the disclosure is not limited thereto. The second data conductive layer may also include more first voltage wirings VL1 and more second voltage wirings VL2.

The second data conductive layer may be, but is not limited to, a single layer or a multilayer made of any one or more of molybdenum (Mo), aluminum (Al), chromium (Cr), gold (Au), titanium (Ti), nickel (Ni), neodymium (Nd), copper (Cu), and alloys thereof. However, the disclosure is not limited thereto.

A first planarization layer 19 is disposed on the second data conductive layer. The first planarization layer 19 may include an organic insulating material such as polyimide (PI) and perform a surface planarization function.

First banks 40, electrodes 21 and 22, the light emitting elements 30, the second bank 45, and contact electrodes 26 and 27 are disposed on the first planarization layer 19. Insulating layers 51 to 54 may be further disposed on the first planarization layer 19.

The first banks 40 may be directly disposed on the first planarization layer 19. The first banks 40 may extend in the second direction DR2 in each subpixel PXn but may end at a position spaced apart from a boundary between the subpixels PXn so as not to extend to another subpixel PXn neighboring in the second direction DR2. The first banks 40 may be spaced apart from each other to face each other in the first direction DR1. The first banks 40 may be spaced apart from each other to form an area in which the light emitting elements 30 are disposed between the first banks 40. The first banks 40 may be disposed in each subpixel PXn to form linear patterns in the display area DPA of the display device 10. Although FIG. 3 illustrates two first banks 40, the disclosure is not limited thereto. The number of the first banks 40 may be increased depending on the number of the electrodes 21 and 22 to be described below.

At least a portion of each of the first banks 40 may protrude from an upper surface of the first planarization layer 19. The protruding portion of each of the first banks 40 may have inclined side surfaces, and light emitted from the light emitting elements 30 may travel toward the inclined side surfaces of the first banks 40. The electrodes 21 and 22 disposed on the first banks 40 may include a material having high reflectivity, and light emitted from the light emitting elements 30 may be reflected by the electrodes 21 and 22 disposed on the side surfaces of the first banks 40 to travel toward above the first planarization layer 19. For example, the first banks 40 may provide an area where the light emitting elements 30 are located while functioning as reflective barriers that reflect light emitted from the light emitting elements 30 in an upward direction. The side surfaces of the first banks 40 may be inclined in a linear shape. However, the disclosure is not limited thereto, and outer surfaces of the first banks 40 may also have a curved semi-circular or semi-elliptical shape In an embodiment, the first banks 40 may include an organic insulating material such as polyimide (PI), but the disclosure is not limited thereto.

The electrodes 21 and 22 are disposed on the first banks 40 and the first planarization layer 19. The electrodes 21 and 22 may include the first electrode 21 and the second electrode 22. The first electrode 21 and the second electrode 22 may extend in the second direction DR2 and may be spaced apart from each other to face each other in the first direction DR1. The first electrode 21, the second electrode 22, and the first banks 40 may have a substantially identical or similar shape, but lengths of the first electrode 21 and the second electrode 22 measured in the second direction DR2 may be greater than those of the first banks 40.

Each of the first electrode 21 and the second electrode 22 may extend in the second direction DR2 in each subpixel PXn, but may be separated from another electrode 21 or 22 in the cutout area CBA of each subpixel PXn. In some embodiments, the cutout area CBA may be disposed between the emission areas EMA of subpixels PXn neighboring each other in the second direction DR2, and the first electrode 21 and the second electrode 22 may be separated, in the cutout area CBA, from another first electrode 21 and another second electrode 22 disposed in another subpixel PXn neighboring the subpixel PXn in the second direction DR2. The first electrode 21 and the second electrode 22 may be formed by placing the light emitting elements 30 and cutting the electrodes 21 and 22 in the cutout area CBA during the manufacturing process of the display device 10. However, the disclosure is not limited thereto, and some electrodes 21 and 22 may not be separated from each other for each subpixel PXn but may extend beyond the subpixels PXn neighboring each other in the second direction DR2, or only one of the first electrode 21 and the second electrode 22 may be separated.

The first electrode 21 may be electrically connected to the first transistor TR1 through a first contact hole CT1, and the second electrode 22 may be electrically connected to the second voltage wiring VL2 through a second contact hole CT2. For example, the first electrode 21 may overlap a portion of the second bank 45 which extends in the first direction DR1 and may contact the first conductive pattern CDP through the first contact hole CT1 penetrating the first planarization layer 19. The second electrode 22 may also overlap a portion of the second bank 45 which extends in the first direction DR1 and may contact the second voltage wiring VL2 through the second contact hole CT2 penetrating the first planarization layer 19. However, the disclosure is not limited thereto. In some embodiments, the first contact hole CT1 and the second contact hole CT2 may be disposed in the emission area EMA surrounded by the second bank 45 so as not to overlap the second bank 45.

Although one first electrode 21 and one second electrode 22 are disposed in each subpixel PXn in the drawings, the disclosure is not limited thereto. In some embodiments, more first electrodes 21 and more second electrodes 22 may be disposed in each subpixel PXn. The first electrode 21 and the second electrode 22 disposed in each subpixel PXn may not necessarily extend in a direction and may be disposed in various suitable structures. For example, the first electrode 21 and the second electrode 22 may be partially curved or bent, or any one of the first electrode 21 and the second electrode 22 may surround the other electrode. The structure or shape in which the first electrode 21 and the second electrode 22 are provided is not particularly limited as long as the first electrode 21 and the second electrode 22 are at least partially spaced apart from each other to face each other so that an area where the light emitting elements 30 are to be located can be formed between the first electrode 21 and the second electrode 22.

The first electrode 21 and the second electrode 22 may be disposed on the first banks 40, respectively. The first electrode 21 and the second electrode 22 may be spaced apart from each other to face each other in the first direction DR1, and the light emitting elements 30 may be disposed between the first electrode 21 and the second electrode 22. At least one end of each of the light emitting elements 30 disposed between the first electrode 21 and the second electrode 22 may be electrically connected to the first electrode 21 and the second electrode 22.

In some embodiments, the first electrode 21 and the second electrode 22 may be formed to have greater widths than the first banks 40. For example, the first electrode 21 and the second electrode 22 may cover the outer surfaces of the first banks 40. The first electrode 21 and the second electrode 22 may be disposed on the side surfaces of the first banks 40, and a distance between the first electrode 21 and the second electrode 22 may be smaller than a distance between the first banks 40. At least a portion of each of the first electrode 21 and the second electrode 22 may be directly disposed on the first planarization layer 19.

Each of the electrodes 21 and 22 may include a conductive material having high reflectivity. For example, each of the electrodes 21 and 22 may include a metal such as silver (Ag), copper (Cu), or aluminum (Al) as a material having high reflectivity or may be an alloy containing aluminum (Al), nickel (Ni), or lanthanum (La). Each of the electrodes 21 and 22 may reflect light, which travels toward the side surfaces of the first banks 40 after being emitted from the light emitting elements 30, toward above each subpixel PXn.

However, the disclosure is not limited thereto, and each of the electrodes 21 and 22 may further include a transparent conductive material. For example, each of the electrodes 21 and 22 may include a material such as indium tin oxide (ITO), indium zinc oxide (IZO), or indium-tin-zinc oxide (ITZO). In some embodiments, each of the electrodes 21 and 22 may have a structure in which at least one layer formed of a transparent conductive material and at least one metal layer having high reflectivity are stacked each other, or may be formed as a single layer including the transparent conductive material and the metal layer. For example, each of the electrodes 21 and 22 may have a stacked structure of ITO/Ag/ITO, ITO/Ag/IZO, or ITO/Ag/ITZO/IZO.

The electrodes 21 and 22 may be electrically connected to the light emitting elements 30, and a voltage may be applied to the electrodes 21 and 22 so that the light emitting elements 30 can emit light. For example, the electrodes 21 and 22 may be electrically connected to the light emitting elements 30 through the contact electrodes 26 and 27 to be described below and may transmit received electrical signals to the light emitting elements 30 through the contact electrodes 26 and 27.

In an embodiment, any one of the first electrode 21 and the second electrode 22 may be electrically connected to anodes of the light emitting elements 30, and the other may be electrically connected to cathodes of the light emitting elements 30. However, the disclosure is not limited thereto, and the opposite case may also be true.

Each of the electrodes 21 and 22 may be utilized to form an electric field in each subpixel PXn so as to align the light emitting elements 30. The light emitting elements 30 may be arranged between the first electrode 21 and the second electrode 22 by the electric field formed on the first electrode 21 and the second electrode 22. In an embodiment, the light emitting elements 30 of the display device 10 may be sprayed onto the electrodes 21 and 22 through an inkjet process. In case that ink including the light emitting elements 30 is sprayed onto the electrodes 21 and 22, an alignment signal is transmitted to the electrodes 21 and 22 to generate an electric field. The light emitting elements 30 dispersed in the ink may be aligned on the electrodes 21 and 22 by a dielectrophoretic force applied by the electric field generated on the electrodes 21 and 22.

The second bank 45 may be disposed on the first planarization layer 19. The second bank 45 may include portions extending in the first direction DR1 and the second direction DR2 in a plan view and may be disposed in a grid pattern over the entire display area DPA. The second bank 45 may be disposed at the boundary of each subpixel PXn to separate neighboring subpixels PXn from each other. According to an embodiment, the second bank 45 may be formed to have a greater height than the first banks 40. The second bank 45 may prevent ink from overflowing into adjacent subpixels PXn in an inkjet printing process during the manufacturing process of the display device 10. The second bank 45 may separate inks, in which different light emitting elements 30 are dispersed for different subpixels PXn, from each other so as to prevent mixing of the inks with each other.

The second bank 45 may surround the emission area EMA and the cutout area CBA disposed in each subpixel PXn to separate them from each other. The first electrode 21 and the second electrode 22 may extend in the second direction DR2 to cross a portion of the second bank 45 which extends in the first direction DR1. A portion of the second bank 45 which extends in the second direction DR2 may have a greater width between the emission areas EMA than between the cutout areas CBA. Accordingly, the distance between the cutout areas CBA may be smaller than the distance between the emission areas EMA. Each of the electrodes 21 and 22 may overlap the second bank 45 disposed between the cutout area CBA and the emission area EMA, and the contact holes CT1 and CT2 may be formed in the overlapping portions.

The first electrode 21 and the second electrode 22 may also be disposed in the cutout area CBA beyond the second bank 45 surrounding the emission area EMA of each subpixel PXn. As described above, the first electrode 21 and the second electrode 22 may be separated from another first electrode 21 and another second electrode 22 through a process of cutting a portion in the cutout area CBA during the manufacturing process of the display device 10.

Similar to the first banks 40, the second bank 45 may include polyimide (P1), but the disclosure is not limited thereto.

A first insulating layer 51 is disposed on the first planarization layer 19. The first insulating layer 51 may be disposed between the first banks 40 or between the first electrode 21 and the second electrode 22 in the emission area EMA and may extend in the direction in which the first electrode 21 and the second electrode 22 extend, for example, the second direction DR2. The first insulating layer 51 disposed in each subpixel PXn may form linear patterns over the entire display area DPA. The first insulating layer 51 may insulate the first electrode 21 and the second electrode 22 from each other. The first insulating layer 51 may form an area in which the light emitting elements 30 are disposed, and may prevent semiconductor layers of the light emitting elements 30 from being damaged by directly contacting the electrodes 21 and 22.

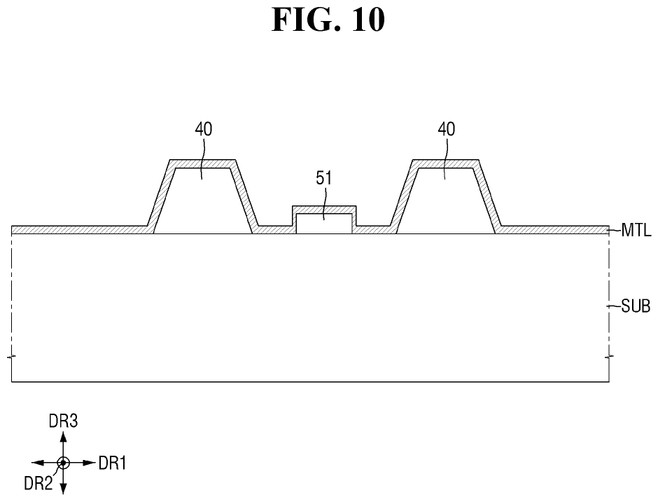

According to an embodiment, during the process of manufacturing the display device 10, the process of forming the first insulating layer 51 may be performed before the process of forming the first electrode 21 and the second electrode 22. The first electrode 21 and the second electrode 22 may be formed through a process of partially removing an electrode layer MTL (see FIG. 10) covering the first insulating layer 51. Accordingly, the first insulating layer 51 is disposed not to overlap the electrodes 21 and 22 in the thickness direction so as not to cover the electrodes 21 and 22. Since the electrodes 21 and 22 are formed after the first insulating layer 51 is formed, it is possible to prevent the first electrode 21 and the second electrode 22 from short-circuiting due to incomplete removal of materials that form the electrodes. Furthermore, it is possible to prevent the light emitting elements 30, having ends disposed on the electrodes 21 and 22, from being inclined toward any one electrode in case that the electrode layer MTL is etched more than designed. The arrangement of the first insulating layer 51, each of the electrodes 21 and 22, and the light emitting elements 30 will be described in detail below.

The light emitting elements 30 may be disposed on the first insulating layer 51. The light emitting elements 30 may be spaced apart from each other in the second direction DR2 in which each of the electrodes 21 and 22 extends, and may be aligned substantially parallel to each other. A distance between the light emitting elements 30 is not particularly limited. The light emitting elements 30 may extend in a direction, and the direction in which the electrodes 21 and 22 extend and the direction in which the light emitting elements 30 extend may be substantially perpendicular to each other. However, the disclosure is not limited thereto, and the light emitting elements 30 may also extend in a direction not perpendicular but oblique to the direction in which the electrodes 21 and 22 extend.

The light emitting elements 30 may include active layers 36 including different materials to emit light of different wavelength bands. The display device 10 may include the light emitting elements 30 which emit light of different wavelength bands. For example, each light emitting element 30 of the first subpixel PX1 may include an active layer 36 that emits light of the first color a central wavelength band of which is a first wavelength, each light emitting element 30 of the second subpixel PX2 may include an active layer 36 that emits light of the second color a central wavelength band of which is a second wavelength, and each light emitting element 30 of the third subpixel PX3 may include an active layer 36 that emits light of the third color a central wavelength band of which is a third wavelength. Accordingly, the light of the first color, the light of the second color, and the light of the third color may be output from the first subpixel PX1, the second subpixel PX2, and the third subpixel PX3, respectively. However, the disclosure is not limited thereto. In some embodiments, the first subpixel PX1, the second subpixel PX2, and the third subpixel PX3 may include the light emitting elements 30 of a same type to emit light of substantially a same color.

Ends of each light emitting element 30 may be respectively disposed on the electrodes 21 and 22 between the first banks 40. For example, an end of each light emitting element 30 may be disposed on the first electrode 21, and another end may be disposed on the second electrode 22. A length by which the light emitting elements 30 extend may be greater than the distance between the first electrode 21 and the second electrode 22, and ends of each light emitting element 30 may be disposed on the first electrode 21 and the second electrode 22.

Each of the light emitting elements 30 may include layers located in a direction perpendicular to the first substrate 11 or an upper surface of the first planarization layer 19. The direction in which the light emitting elements 30 of the display device 10 extend may be parallel to the first planarization layer 19, and the semiconductor layers included in each of the light emitting elements 30 may be sequentially located in a direction parallel to the upper surface of the first planarization layer 19. However, the disclosure is not limited thereto. In some embodiments, in case that each of the light emitting elements 30 has a different structure, the layers may be located in a direction perpendicular to the first planarization layer 19.

E of each light emitting element 30 may contact the contact electrodes 26 and 27, respectively. According to an embodiment, an insulating film 38 may not be formed on end surfaces of each light emitting element 30 in the direction in which the light emitting elements 30 extend, thereby exposing some of the semiconductor layers. Thus, the exposed semiconductor layers may contact the contact electrodes 26 and 27. However, the disclosure is not limited thereto. In some embodiments, at least a portion of the insulating film 38 of each light emitting element 30 may be removed to partially expose side surfaces of both ends of the semiconductor layers. The exposed side surfaces of the semiconductor layers may directly contact the contact electrodes 26 and 27.

A second insulating layer 52 may be disposed on a portion of each light emitting element 30 disposed between the first electrode 21 and the second electrode 22. The second insulating layer 52 may partially cover outer surfaces of the light emitting elements 30. The second insulating layer 52 may be disposed on the light emitting elements 30, but may not cover an end and another end of each light emitting element 30 so that the contact electrodes 26 and 27 may contact ends of each light emitting element 30. A portion of the second insulating layer 52 which is disposed on the light emitting elements 30 may extend in the second direction DR2 on the first insulating layer 51 in a plan view. For example, the second insulating layer 52 may form a linear or island-shaped pattern in each subpixel PXn. The second insulating layer 52 covering the outer surfaces of the light emitting elements 30 may protect the light emitting elements 30 while anchoring the light emitting elements 30 in the manufacturing process of the display device 10.

The contact electrodes 26 and 27 and a third insulating layer 53 may be disposed on the second insulating layer 52.

The contact electrodes 26 and 27 may extend in a direction. The contact electrodes 26 and 27 may contact the light emitting elements 30 and the electrodes 21 and 22. A first contact electrode 26 and a second contact electrode 27 of the contact electrodes 26 and 27 may be disposed on a portion of the first electrode 21 and a portion of the second electrode 22, respectively. The first contact electrode 26 may be disposed on the first electrode 21, the second contact electrode 27 may be disposed on the second electrode 22, and each of the first contact electrode 26 and the second contact electrode 27 may extend in the second direction DR2. The first contact electrode 26 and the second contact electrode 27 may be spaced apart from each other in the first direction DR1 and may form stripe patterns in the emission area EMA of each subpixel PXn.

In some embodiments, widths of the first contact electrode 26 and the second contact electrode 26 measured in a direction may be equal to or smaller than widths of the first electrode 21 and the second electrode 22 measured in the direction, respectively. The first contact electrode 26 and the second contact electrode 26 may respectively contact an end and another end of each light emitting element 30 and partially cover upper surfaces of the first electrode 21 and the second electrode 22.

As described above, the semiconductor layers may be exposed on end surfaces of each light emitting element 30 in the direction in which the light emitting elements 30 extend, and the first contact electrode 26 and the second contact electrode 27 may contact each light emitting element 30 at the end surfaces where the semiconductor layers are exposed. An end of each light emitting element 30 may be electrically connected to the first electrode 21 through the first contact electrode 26, and another end may be electrically connected to the second electrode 22 through the second contact electrode 27.

Although FIG. 3 illustrates that a first contact electrode 26 and a second contact electrode 27 are in a subpixel PXn, the disclosure is not limited thereto. The number of the first contact electrodes 26 and the second contact electrodes 27 may vary according to the number of the first electrodes 21 and the second electrodes 22 in each subpixel PXn.

The third insulating layer 53 is disposed on the first contact electrode 26. The third insulating layer 53 may electrically insulate the first contact electrode 26 and the second contact electrode 27 from each other. The third insulating layer 53 may cover the first contact electrode 26, but may not be disposed on another end of each light emitting element 30 so that the light emitting elements 30 can contact the second contact electrode 27. The third insulating layer 53 on an upper surface of the second insulating layer 52 may partially contact the first contact electrode 26 and the second insulating layer 52. A side surface of the third insulating layer 53 in a direction in which the second electrode 22 is disposed may be aligned with a side surface of the second insulating layer 52. The third insulating layer 53 may also be disposed in the non-emission area, for example, on the first insulating layer 51 disposed on the first planarization layer 19. However, the disclosure is not limited thereto.

The second contact electrode 27 is disposed on the second electrode 22, the second insulating layer 52, and the third insulating layer 53. The second contact electrode 27 may contact another end of each light emitting element 30 and the exposed upper surface of the second electrode 22. The another end of each light emitting element 30 may be electrically connected to the second electrode 22 through the second contact electrode 27.

The second contact electrode 27 may partially contact the second insulating layer 52, the third insulating layer 53, the second electrode 22, and the light emitting elements 30. The first contact electrode 26 and the second contact electrode 27 may not contact each other due to the second insulating layer 52 and the third insulating layer 53. However, the disclosure is not limited thereto. In some embodiments, the third insulating layer 53 may be omitted.

The contact electrodes 26 and 27 may include a conductive material such as ITO, IZO, ITZO, or aluminum (Al). For example, the contact electrodes 26 and 27 may include a transparent conductive material, and light emitted from the light emitting elements 30 may pass through the contact electrodes 26 and 27 to travel toward the electrodes 21 and 22. Each of the electrodes 21 and 22 may include a material having high reflectivity, and the electrodes 21 and 22 placed on the inclined side surfaces of the first banks 40 may reflect incident light toward above the first substrate 11. However, the disclosure is not limited thereto.

A fourth insulating layer 54 may be disposed on the entire surface of the first substrate 11. The fourth insulating layer 54 may function to protect members on the first substrate 11 from the external environment.

Each of the first insulating layer 51, the second insulating layer 52, the third insulating layer 53, and the fourth insulating layer 54 described above may include an inorganic insulating material or an organic insulating material. In an embodiment, the first insulating layer 51, the second insulating layer 52, the third insulating layer 53, and the fourth insulating layer 54 may include an inorganic insulating material such as silicon oxide (SiOₓ), silicon nitride (SiNₓ), silicon oxynitride (SiOₓN_{y}), aluminum oxide (Al₂O₃), or aluminum nitride (AlN). As another example, the first insulating layer 51, the second insulating layer 52, the third insulating layer 53, and the fourth insulating layer 54 may include an organic insulating material such as acrylic resin, epoxy resin, phenolic resin, polyamide resin, polyimide resin, unsaturated polyester resin, polyphenylene resin, polyphenylene sulfide resin, benzocyclobutene, cardo resin, siloxane resin, silsesquioxane resin, polymethyl methacrylate, polycarbonate, or polymethyl methacrylate-polycarbonate synthetic resin. However, the disclosure is not limited thereto.

As described above, the first insulating layer 51 may be disposed between the first electrode 21 and the second electrode 22. The first insulating layer 51 may be formed before the first electrode 21 and the second electrode 22 are formed. According to an embodiment, the first insulating layer 51 may not overlap each of the electrodes 21 and 22, and the first electrode 21 and the second electrode 22 may contact side surfaces of the first insulating layer 51. By forming the electrodes 21 and 22 after the first insulating layer 51 is formed, it is possible to prevent the distance between the first electrode 21 and the second electrode 22 from deviating from a design value.

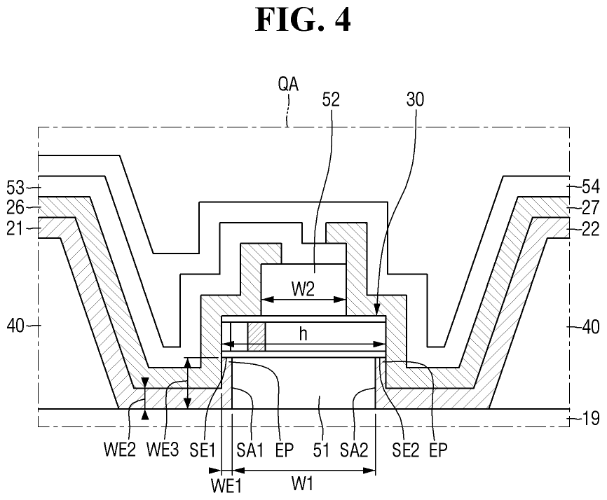

FIG. 4 is a schematic enlarged view of portion QA of FIG. 3.

Referring to FIG. 4, the first insulating layer 51 is directly disposed on the first planarization layer 19 between the first banks 40. The first electrode 21 and the second electrode 22 may also be partially directly disposed on the first planarization layer 19. For example, the first electrode 21 and the second electrode 22 may have a greater width than the first banks 40 and may cover the first banks 40 while a portion of each of the first electrode 21 and the second electrode 22 is directly disposed on the first planarization layer 19.

As described above, ends of each light emitting element 30 disposed on the first insulating layer 51 may be disposed on the first electrode 21 and the second electrode 22. The first electrode 21 and the second electrode 22 may be designed such that the distance between them is smaller than a length h of each light emitting element 30 and may be disposed on the first planarization layer 19 or the first banks 40. In case that the distance between the first electrode 21 and the second electrode 22 is too small, the first electrode 21 and the second electrode 22 may short-circuit due to a residual layer resulting from incomplete removal of a material that forms the electrodes 21 and 22 in a process of etching the material. In case that the distance between the first electrode 21 and the second electrode 22 is too large, any one end of each light emitting element 30 may be disposed between the first electrode 21 and the second electrode 22. Thus, the light emitting elements 30 may be inclined in a cross-sectional view. The contact electrodes 26 and 27 formed in a subsequent process may not smoothly contact the end surfaces of each light emitting element 30.

Since the first electrode 21 and the second electrode 22 include a metal material and are disposed on the first banks 40, the amount of light exposure may differ from position to position on each of the electrodes 21 and 22 due to a step formed by the first banks 40. Cross sections of the electrodes 21 and 22 remaining after etching may not be smooth, or the distance between the first electrode 21 and the second electrode 22 may deviate from a design value.

According to an embodiment, after the first insulating layer 51 is formed first during the manufacturing process of the display device 10, the first electrode 21 and the second electrode 22 may be formed. The first electrode 21 and the second electrode 22 may be formed by forming an electrode layer covering the first insulating layer 51 and removing the electrode layer to expose an upper surface of the first insulating layer 51. Since the first insulating layer 51 includes an inorganic insulating material or an organic insulating material, a cross section or side surfaces of the first insulating layer 51 formed through an etching process may be smooth, and it may be relatively easy to form a width of the first insulating layer 51 according to a design value. By forming the first electrode 21 and the second electrode 22 after forming the first insulating layer 51, it is possible to form the distance between the first electrode 21 and the second electrode 22 according to a design value, thereby minimizing process dispersion (or variation). Accordingly, the light emitting elements 30 may be disposed on the first insulating layer 51 such that ends thereof are disposed on the electrodes 21 and 22, respectively. This can prevent poor contact of the light emitting elements 30 with the contact electrodes 26 and 27.

In an embodiment, the first insulating layer 51 may be disposed between the first electrode 21 and the second electrode 22, and a width W1 of the first insulating layer 51 may be equal to the distance between the first electrode 21 and the second electrode 22. For example, side surfaces SA1 and SA2 of the first insulating layer 51 may contact the first electrode 21 and the second electrode 22, respectively. The first electrode 21 and the second electrode 22 may be formed by forming an electrode layer covering the first insulating layer 51 and partially removing the electrode layer. For example, after the electrode layer is placed to cover both the side surfaces and the upper surface of the first insulating layer 51, it may be removed to expose the upper surface of the first insulating layer 51. The first insulating layer 51 thus formed may not overlap each of the electrodes 21 and 22 in the thickness direction. The first electrode 21 and the second electrode 22 may contact side surfaces SA1 and SA2 of the first insulating layer 51, and the distance between them may be equal to the width W1 of the first insulating layer 51.

In an embodiment, the width W1 of the first insulating layer 51 may be smaller than the length h of each light emitting element 30, but may be greater than a width W2 of the second insulating layer 52. Since the first insulating layer 51 has a width W1 sufficient to allow the light emitting elements 30 to be disposed thereon but smaller than the length h of each light emitting light 30, ends of each light emitting element 30 may be disposed on the first electrode 21 and the second electrode 22. The width W1 of the first insulating layer 51 may be adjusted within a range in which the light emitting elements 30 can be horizontally disposed in consideration of thicknesses of the electrodes 21 and 22 disposed on side surfaces SA1 and SA2 and the length h of each light emitting element 30.

The second insulating layer 52 has a width W2 that is smaller than at least the length h of each light emitting element 30 so as not to cover ends of each light emitting element 30. The first contact electrode 26 and the second contact electrode 27 may respectively contact the ends of each light emitting element 30 while at least a portion of each of the first contact electrode 26 and the second contact electrode 27 is disposed on the second insulating layer 52. However, the second insulating layer 52 may not have a smaller width than the first insulating layer 51, and the width W2 of the second insulating layer 52 may vary within a range in which the second insulating layer 52 can perform the function of anchoring the light emitting elements 30 as described above.

Each of the first electrode 21 and the second electrode 22 may include a first portion EP contacting the first insulating layer 51. The first insulating layer 51 may include a first side surface SA1 contacting the first portion EP of the first electrode 21 and a second side surface SA2 contacting the first portion EP of the second electrode 22. The first insulating layer 51 may include an insulating material, and side surfaces SA1 and SA2 of the first insulating layer 51 may be formed perpendicular to the upper surface of the first planarization layer 19 in an etching process. A contact surface between each of the first electrode 21 and the second electrode 22 and the first insulating layer 51 may be perpendicular to the upper surface of the first planarization layer 19.

According to an embodiment, a width WE1 of the first portion EP of each of the first electrode 21 and the second electrode 22 may be smaller than a thickness WE2 of other portions thereof. An electrode layer covering the first insulating layer 51 may have a substantially uniform thickness, but a portion thereof formed on the side surfaces of the first insulating layer 51 may be relatively thin due to a step formed by the first insulating layer 51. The thickness WE2 of each of the first electrode 21 and the second electrode 22 may be a thickness measured in portions thereof excluding the first portion EP, and the portions may have substantially a same thickness. However, the first portions EP of the electrodes 21 and 22 may have a relatively small width WE1 as they are formed along the side surfaces SA1 and SA2 of the first insulating layer 51.

A thickness of the first insulating layer 51 may be greater than the thickness WE2 measured in the portions other than the first portion EP1 of each of the first electrode 21 and the second electrode 22. The first portions EP of the first electrode 21 and the second electrode 22 may contact side surfaces SA1 and SA2 of the first insulating layer 51 in the thickness direction of the first insulating layer 51. For example, a thickness WE3 of each first portion EP may be substantially equal to the thickness of the first insulating layer 51. Even if the thicknesses of the first electrode 21 and the second electrode 22 are smaller than the thickness of the first insulating layer 51, an electrode layer may be placed to cover side surfaces SA1 and SA2 along an outer surface of the first insulating layer 51 during the manufacturing process. Accordingly, the first portions EP of the first electrode 21 and the second electrode 22 may also fully contact the side surfaces SA1 and SA2 in the thickness direction of the first insulating layer 51. The first contact electrode 26 and the second contact electrode 27 may contact end surfaces of each light emitting element 30 and may also contact the first portions EP of the electrodes 21 and 22.

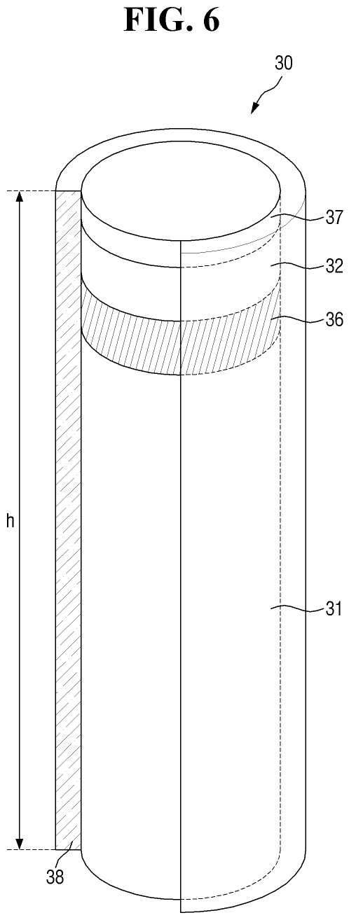

In an embodiment, the upper surface of the first insulating layer 51 and upper surfaces SE1 and SE2 of the first portions EP of the electrodes 21 and 22 may lie in a same plane. Each light emitting element 30 may be disposed on the first insulating layer 51 such that ends thereof lie on the first portions EP of the electrodes 21 and 22, respectively. The upper surfaces SE1 and SE2 of the first portions EP of the electrodes 21 and 22 may contact a side surface of each light emitting element 30. However, as will be described below, each light emitting element 30 may include the insulating film 38 (see FIG. 6) surrounding outer surfaces of semiconductor layers. Thus, the first portion EP of each of the electrodes 21 and 22 may directly contact the insulating film 38 of each light emitting element 30 and may not contact the semiconductor layers.

In the display device 10 according to the embodiment, the first insulating layer 51 on which the light emitting elements 30 are disposed is formed before the first electrode 21 and the second electrode 22. The first insulating layer 51 may be disposed not to cover the first electrode 21 and the second electrode 22, and the distance between the first electrode 21 and the second electrode 22 may be formed to be the same as the width of the first insulating layer 51. The distance between the electrodes 21 and 22 may be adjusted through the width W1 of the first insulating layer 51 in consideration of the length h of each light emitting element 30. Since the first insulating layer 51 includes an insulating material, it is easy to form the shape or width of the first insulating layer 51 according to a design value. Accordingly, the distance between the first electrode 21 and the second electrode 22 can be more easily adjusted, and a short circuit between the electrodes 21 and 22 due to poor etching of the material that forms the first electrode 21 and the second electrode 22 can be prevented. Therefore, in the display device 10 according to the embodiment, the light emitting elements 30 may be horizontally disposed on the first insulating layer 51 and the electrodes 21 and 22, and misalignment of the light emitting elements 30 and poor contact of the light emitting elements 30 with the contact electrodes 26 and 27 may be minimized.

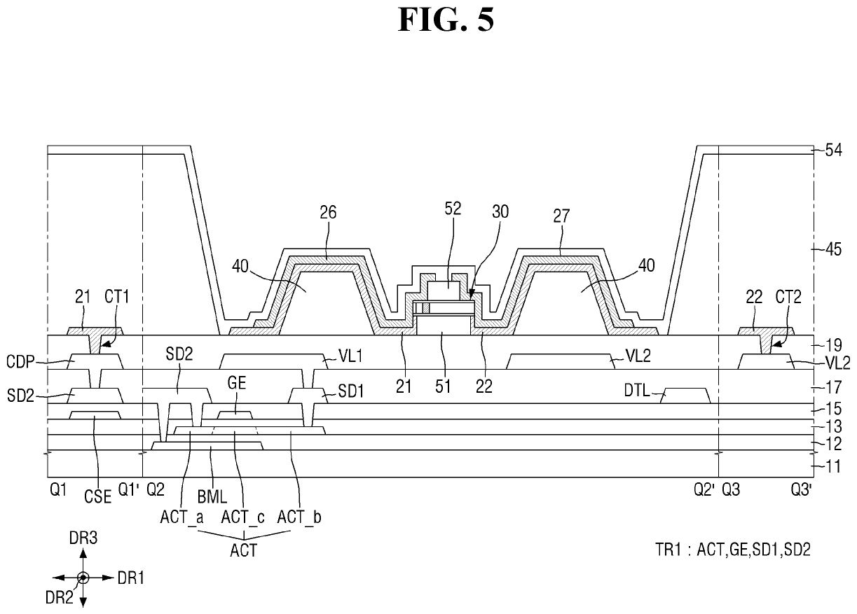

FIG. 5 is a schematic partial cross-sectional view of a display device according to another embodiment.

Referring to FIG. 5, in the display device 10, a third insulating layer 53 may be omitted. A portion of a second contact electrode 27 may be directly disposed on a second insulating layer 52, and a first contact electrode 26 and the second contact electrode 27 may be spaced apart from each other on the second insulating layer 52. According to an embodiment, even if the third insulating layer 53 is omitted from the display device 10, the second insulating layer 52 may include an organic insulating material to perform the function of anchoring the light emitting elements 30. Both the first contact electrode 26 and the second contact electrode 27 may be simultaneously formed through a patterning process. The embodiment of FIG. 5 is the same as the embodiment of FIG. 3 except that the third insulating layer 53 is omitted. Thus, any redundant description will be omitted below.

FIG. 6 is a schematic view of a light emitting element according to an embodiment.

The light emitting element 30 may be a light emitting diode. Specifically, the light emitting element 30 may be an inorganic light emitting diode having a size of micrometers or nanometers and made of an inorganic material. In case that an electric field is formed in a specific direction between two electrodes facing each other, the inorganic light emitting diode may be aligned between the two electrodes in which polarities are formed. The light emitting element 30 may be aligned between two electrodes by the electric field formed on the electrodes.

The light emitting element 30 according to the embodiment may extend in a direction. The light emitting element 30 may have a shape such as a rod, a wire, a tube, or the like. In an embodiment, the light emitting element 30 may be shaped like a cylinder or a rod. However, the shape of the light emitting element 30 is not limited thereto, and the light emitting element 30 may also have various shapes including polygonal prisms, such as a cube, a rectangular parallelepiped, or a hexagonal prism, and a shape extending in a direction and having a partially inclined outer surface. Semiconductors included in the light emitting element 30 which will be described below may be sequentially arranged or stacked each other in the direction.

The light emitting element 30 may include a semiconductor layer doped with impurities of any conductivity type (e.g., a p-type or an n-type). The semiconductor layer may receive an electrical signal from an external power source and emit light of a specific wavelength band.

Referring to FIG. 6, the light emitting element 30 may include a first semiconductor layer 31, a second semiconductor layer 32, an active layer 36, an electrode layer 37, and an insulating film 38.

The first semiconductor layer 31 may be an n-type semiconductor. In an example, if the light emitting element 30 emits light in a blue wavelength band, the first semiconductor layer 31 may include a semiconductor material having a chemical formula of AlₓGa_{y}In_{1-x-y}N (0≤x≤1, 0≤y≤1, 0≤x+y≤1). For example, the semiconductor material included in the first semiconductor layer 31 may be any one or more of n-type doped AlGaInN, GaN, AlGaN, InGaN, AlN, and InN. The first semiconductor layer 31 may be doped with an n-type dopant, and the n-type dopant may be, for example, Si, Ge, or Sn. In an embodiment, the first semiconductor layer 31 may be n-GaN doped with n-type Si. A length of the first semiconductor layer 31 may be in a range of, but not limited to, about 1.5 μm to about 5 μm.

The second semiconductor layer 32 is disposed on the active layer 36 to be described below. The second semiconductor layer 32 may be a p-type semiconductor. In an example, if the light emitting element 30 emits light in a blue or green wavelength band, the second semiconductor layer 32 may include a semiconductor material having a chemical formula of AlₓGa_{y}In_{1-x-y}N (0≤x≤1, 0≤y≤1, 0≤x+y≤1). For example, the semiconductor material included in the second semiconductor layer 32 may be any one or more of p-type doped AlGaInN, GaN, AlGaN, InGaN, AlN, and InN. The second semiconductor layer 32 may be doped with a p-type dopant, and the p-type dopant may be, for example, Mg, Zn, Ca, Se, or Ba. In an embodiment, the second semiconductor layer 32 may be p-GaN doped with p-type Mg. A length of the second semiconductor layer 32 may be in a range of, but not limited to, about 0.05 μm to about 0.10 μm.

Although FIG. 6 illustrates that each of the first semiconductor layer 31 and the second semiconductor layer 32 is composed of a layer, the disclosure is not limited thereto. According to some embodiments, each of the first semiconductor layer 31 and the second semiconductor layer 32 may further include more layers, for example, a clad layer or a tensile strain barrier reducing (TSBR) layer depending on the material of the active layer 36.

The active layer 36 is disposed between the first semiconductor layer 31 and the second semiconductor layer 32. The active layer 36 may include a material having a single or multiple quantum well structure. In case that the active layer 36 includes a material having a multiple quantum well structure, it may have a structure in which quantum layers and well layers are alternately stacked each other. The active layer 36 may emit light through combination of electron-hole pairs according to electrical signals received through the first semiconductor layer 31 and the second semiconductor layer 32. For example, if the active layer 36 emits light in the blue wavelength band, it may include a material such as AlGaN or AlGaInN. In case that the active layer 36 has a multiple quantum well structure in which a quantum layer and a well layer are alternately stacked each other, the quantum layer may include a material such as AlGaN or AlGaInN, and the well layer may include a material such as GaN or AllnN. In an embodiment, the active layer 36 may include AlGaInN as a quantum layer and AIInN as a well layer to emit blue light of which the central wavelength band is in a range of about 450 nm to about 495 nm as described above.

However, the disclosure is not limited thereto, and the active layer 36 may also have a structure in which a semiconductor material having a large band gap energy and a semiconductor material having a small band gap energy are alternately stacked each other, or may include different group III to V semiconductor materials depending on the wavelength band of light that it emits. Light emitted from the active layer 36 is not limited to light in the blue wavelength band. In some embodiments, the active layer 36 may emit light in a red or green wavelength band. A length of the active layer 36 may be in a range of, but not limited to, about 0.05 μm to about 0.10 μm.

Light emitted from the active layer 36 may be radiated not only through an outer surface of the light emitting element 30 in a longitudinal direction, but also through side surfaces thereof. The direction of light emitted from the active layer 36 is not limited to a direction.

The electrode layer 37 may be an ohmic contact electrode. However, the disclosure is not limited thereto, and the electrode layer 37 may also be a Schottky contact electrode. The light emitting element 30 may include at least one electrode layer 37. Although FIG. 6 illustrates that the light emitting element 30 includes an electrode layer 37, the disclosure is not limited thereto. In some embodiments, the light emitting element 30 may include more electrode layers 37, or the electrode layer 37 may be omitted. The following description of the light emitting element 30 may apply equally even in case that the light emitting element 30 includes a different number of electrode layers 37 or further includes another structure.

In case that the light emitting element 30 is electrically connected to electrodes or contact electrodes in the display device 10 according to the embodiment, the electrode layer 37 may reduce the resistance between the light emitting element 30 and the electrodes or the contact electrodes. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). The electrode layer 37 may include an n-type or p-type doped semiconductor material. The electrode layer 37 may include a same material or different materials, but the disclosure is not limited thereto.

The insulating film 38 surrounds outer surfaces of the semiconductor layers and the electrode layer described above. In an embodiment, the insulating film 38 may surround an outer surface of at least the active layer 36 and extend in the direction in which the light emitting element 30 extends. The insulating film 38 may protect the above members. For example, the insulating film 38 may surround side surfaces of the above members but may expose ends of the light emitting element 30 in the longitudinal direction.

FIG. 6 illustrates that the insulating film 38 extends in the longitudinal direction of the light emitting element 30 to cover from side surfaces of the first semiconductor layer 31 to side surfaces of the electrode layer 37. However, the disclosure is not limited thereto, and the insulating film 38 may cover outer surfaces of the active layer 36 and only some semiconductor layers or may cover only a portion of an outer surface of the electrode layer 37 to partially expose the outer surface of the electrode layer 37. An upper surface of the insulating film 38 may be rounded in a cross-sectional view in an area adjacent to at least one end of the light emitting element 30.

A thickness of the insulating film 38 may be in a range of, but not limited to, about 10 nm to about 1.0 μm. The thickness of the insulating film 38 may be, for example, about 40 nm.

The insulating film 38 may include an insulating material such as silicon oxide (SiOₓ), silicon nitride (SiNₓ), silicon oxynitride (SiOₓN_{y}), aluminum nitride (AlN), or aluminum oxide (Al₂O₃). Accordingly, it can prevent an electrical short circuit that may occur in case that the active layer 36 directly contacts an electrode that transmits an electrical signal to the light emitting element 30. Since the insulating film 38 protects the outer surface of the light emitting element 30 including the active layer 36, a reduction in luminous efficiency can be prevented.

In some embodiments, an outer surface of the insulating film 38 may be treated. The light emitting element 30 dispersed in an ink may be sprayed onto electrodes and aligned. The surface of the insulating film 38 may be hydrophobically or hydrophilically treated so that the light emitting element 30 is kept dispersed in the ink without being agglomerated with other adjacent light emitting elements 30.

A length h of the light emitting element 30 may be in a range of about 1 μm to 10 about μm or about 2 μm to about 6 μm and may be, for example, in a range of about 3 μm to about 5 μm. A diameter of the light emitting element 30 may be in a range of about 30 nm to about 700 nm, and an aspect ratio of the light emitting element 30 may be about 1.2 to about 100. However, the disclosure is not limited thereto, and light emitting elements 30 included in the display device 10 may also have different diameters according to a difference in composition of the active layer 36. The diameter of the light emitting element 30 may be, for example, about 500 nm.

A process of manufacturing the display device 10 according to the embodiment will now be described with further reference to other drawings.

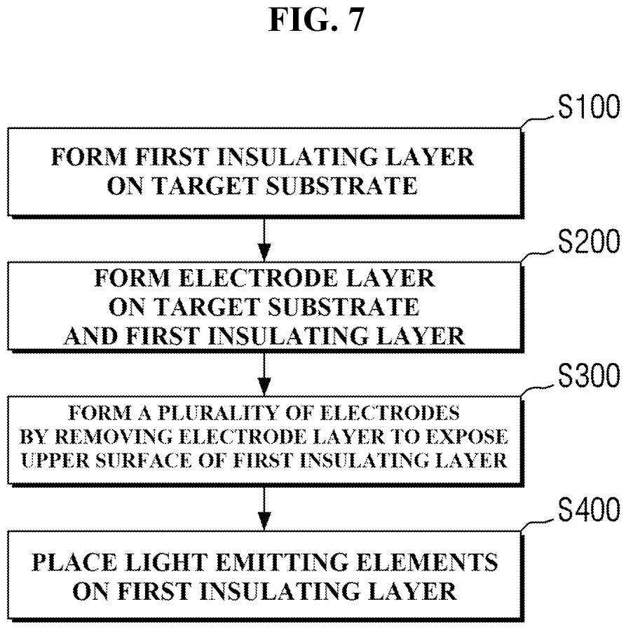

FIG. 7 is a schematic flowchart illustrating a process of manufacturing a display device according to an embodiment.

Referring to FIG. 7, the method of manufacturing the display device 10 according to the embodiment may include preparing a target substrate SUB and forming a first insulating layer 51 on the target substrate SUB (operation S100), forming an electrode layer MTL (see FIG. 10) on the target substrate SUB and the first insulating layer 51 (operation S200), forming electrodes 21 and 22 by removing a portion of the electrode layer MTL to expose an upper surface of the first insulating layer 51 (operation S300), and placing light emitting elements 30 on the first insulating layer 51 (operation S400). As described above, in the display device 10, the first insulating layer 51 is formed before the electrodes 21 and 22 electrically connected to the light emitting elements 30 are formed. After the first insulating layer 51 is formed, the electrode layer MTL is formed to cover the first insulating layer 51, and a first electrode 21 and a second electrode 22 spaced apart from each other are formed by removing a portion of the electrode layer MTL through an etching process. The process of manufacturing the display device 10 will now be described in detail with further reference to other drawings.

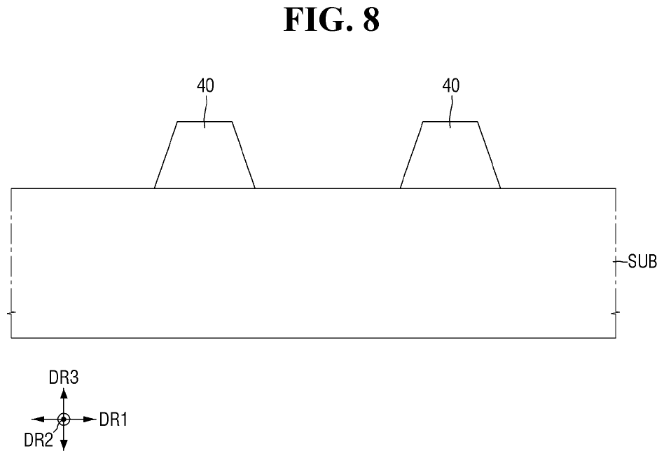

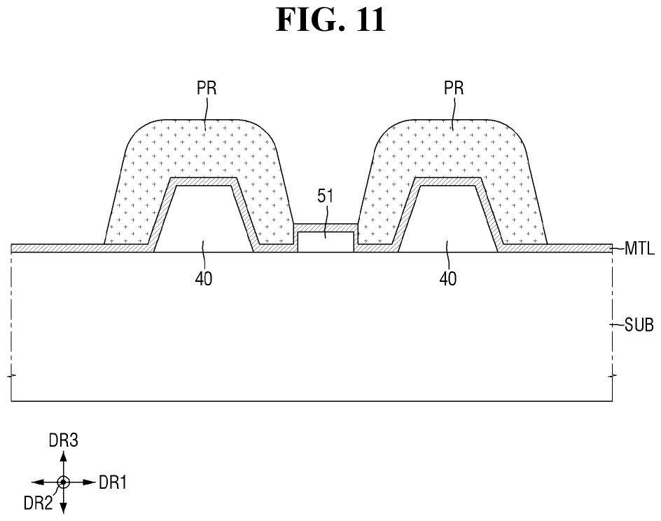

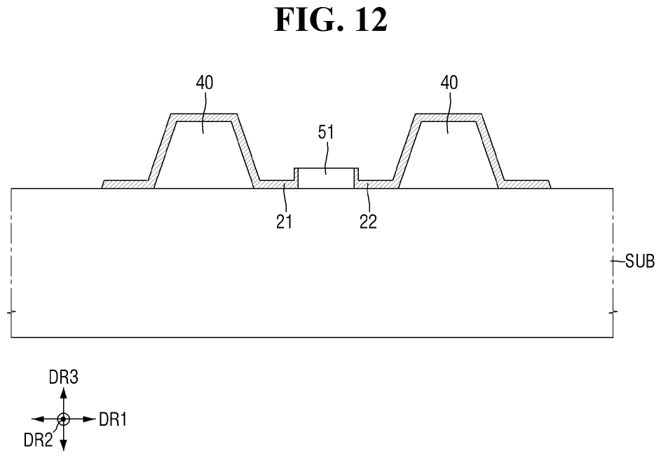

FIGS. 8 to 17 are schematic cross-sectional views illustrating a process of manufacturing a display device according to an embodiment.

First, referring to FIG. 8, a target substrate SUB on which a first insulating layer 51 and electrodes 21 and 22 are disposed is prepared. Although not illustrated in the drawing, the target substrate SUB may include the first substrate 11 described above and circuit elements composed of conductive layers and insulating layers. For ease of description, the target substrate SUB will be illustrated and described as including them. First banks 40 may be placed on the target substrate SUB. The first banks 40 may be spaced apart from each other and may protrude from an upper surface of the target substrate SUB. This is the same as described above. However, in some embodiments, the first banks 40 may be omitted.

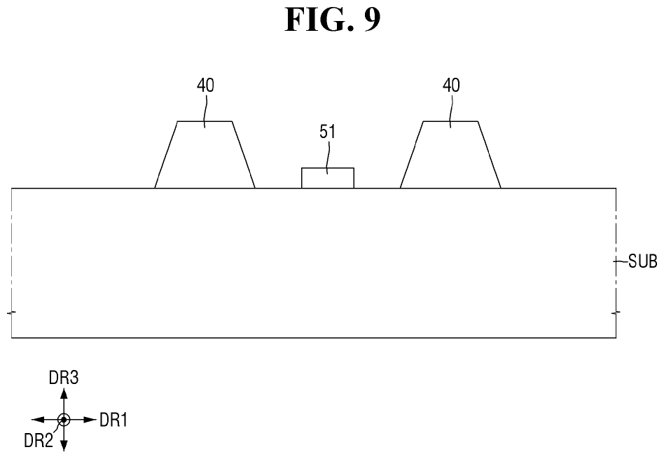

Referring to FIG. 9, the first insulating layer 51 is formed on the target substrate SUB. The first insulating layer 51 may be disposed between the first banks 40. The first insulating layer 51 may be formed by placing a layer, including an insulating material, on the target substrate SUB and the first banks 40 and partially removing the layer through an etching process. In an embodiment, the first insulating layer 51 may be formed by removing an insulating material through a dry etching process. In case that the first insulating layer 51 is formed by the dry etching process, it may be easy to form side surfaces of the first insulating layer 51 perpendicular to the upper surface of the target substrate SUB. Compared with a wet etching process, a dry etching process may have less skew in which a cross section of a material remaining after being etched is inclined. In the manufacturing process of the display device 10, the first insulating layer 51 may be formed by etching an insulating material through a dry etching process, and its side surfaces remaining after the etching may be formed perpendicular to the upper surface of the target substrate SUB. As another example, in an embodiment, the first banks 40 and the first insulating layer 51 may include a same material and thus may be formed in a process.

Referring to FIGS. 10 to 12, an electrode layer MTL is formed on the target substrate SUB and the first insulating layer 51 and partially removed to expose an upper surface of the first insulating layer 51. A portion of the electrode layer MTL may be removed to form a first electrode 21 and a second electrode 22 spaced apart from each other. The electrode layer MTL may be placed to cover the first banks 40 and the first insulating layer 51 disposed on the target substrate SUB. The electrode layer MTL may have substantially a same thickness, but a portion thereof covering the side surfaces of the first insulating layer 51 may be relatively thin due to a step formed by the first insulating layer 51.

After the electrode layer MTL is formed on the target substrate SUB, a photoresist PR is placed on the electrode layer MTL, and a portion of the electrode layer MTL is removed to expose the upper surface of the first insulating layer 51. The photoresist PR placed on the electrode layer MTL may overlap the first banks 40 and may not overlap the first insulating layer 51. In an embodiment, the photoresist PR may be placed on the electrode layer MTL to correspond to the shapes of the first electrode 21 and the second electrode 22. However, the disclosure is not limited thereto.

The first electrode 21 and the second electrode 22 are formed by removing a portion of the electrode layer MTL through an exposure and development process. The first electrode 21 and the second electrode 22 are formed to be spaced apart from each other while contacting side surfaces of the first insulating layer 51. As described above, a distance between the first electrode 21 and the second electrode 22 may be the same as a width of the first insulating layer 51. In case that the first insulating layer 51 is formed first, the distance between the electrodes 21 and 22 may be formed to be similar to a design value compared with when the first electrode 21 and the second electrode 22 are formed without the first insulating layer 51. A skew in which a cross section of each electrode 21 or 22 remaining after etching is inclined is less likely to occur, and process dispersion may be small.

The process of partially removing the electrode layer MTL may be performed by a dry etching process or a wet etching process. In some embodiments, the process of partially removing the electrode layer MTL may include performing a wet etching process and removing a residual layer by using a dry etching process.

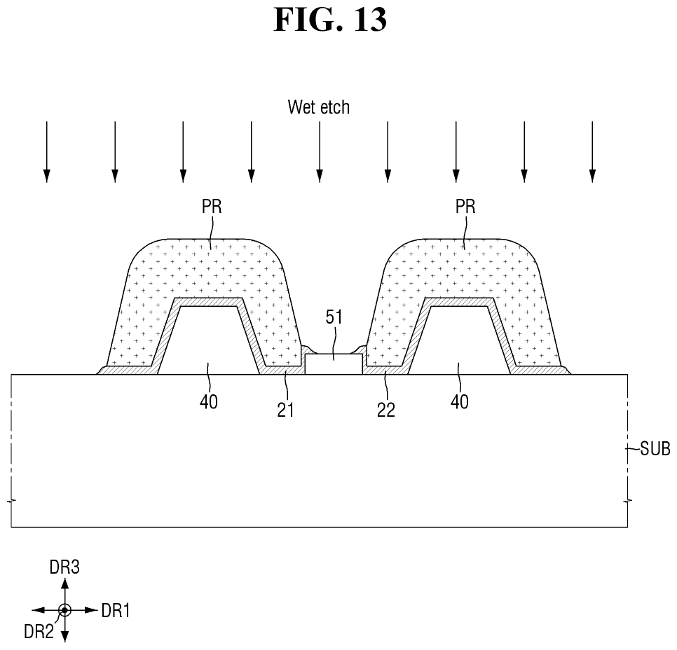

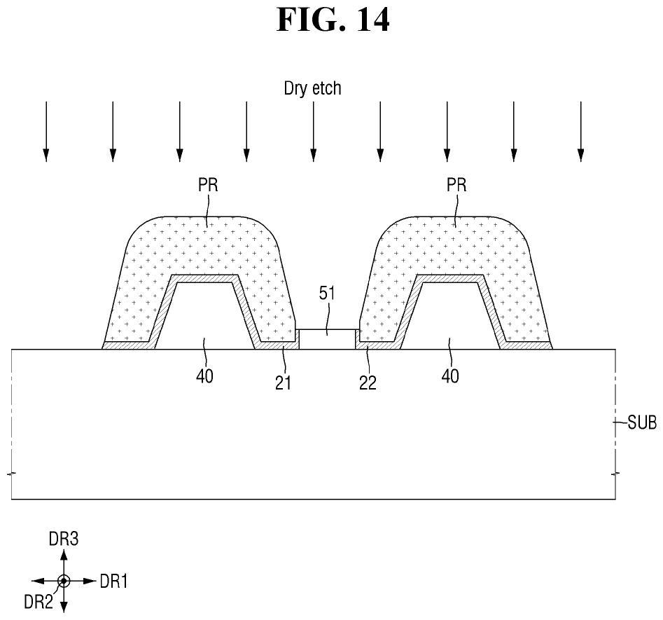

Referring to FIGS. 13 and 14, the process of partially removing the electrode layer MTL may include a first etching process of placing a photoresist PR and removing a portion of the electrode layer MTL by using a wet etching process and a second etching process of removing the electrode layer MTL remaining after the first etching process by using a dry etching process.

The electrode layer MTL and each of the electrodes 21 and 22 may include a same material, and the electrode layer MTL and the first insulating layer 51 may include different materials. Since a wet etching process has a high selectivity for different materials, only the electrode layer MTL can be partially removed with little damage to the first insulating layer 51. However, in the case of the wet etching process, a skew in which a cross section remaining after etching is inclined may be formed, or a residual layer may remain due to incomplete removal of a material. Through a subsequent dry etching process, the electrode layer MTL remaining without being removed may be removed, or the skew formed in the cross section may be removed. According to an embodiment, a wet etching process and a dry etching process may be sequentially performed in the process of partially removing the electrode layer MTL, and the first electrode 21 and the second electrode 22 may be formed without a skew while the upper surface of the first insulating layer 51 is exposed. However, the disclosure is not limited thereto, and the process of forming the electrode layer MTL may also be performed by only a dry etching process or a wet etching process.

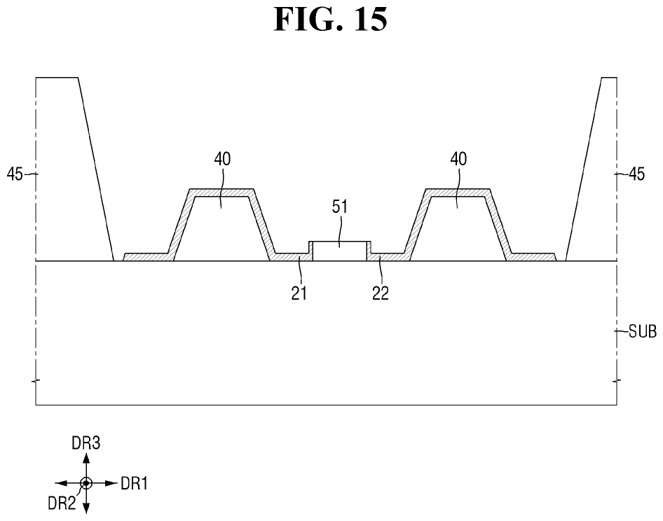

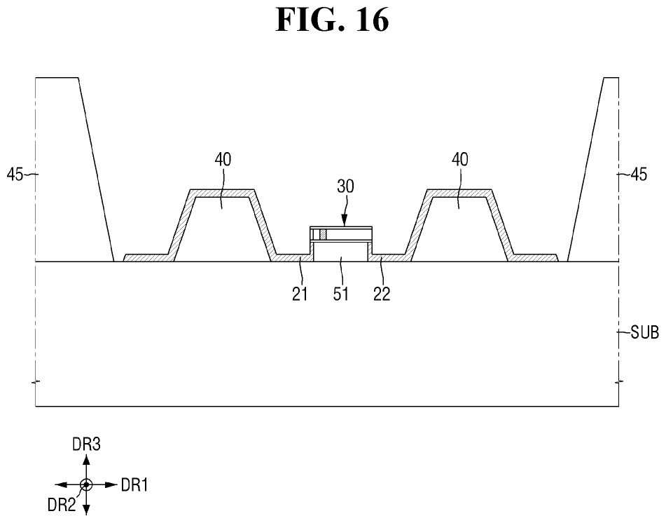

Referring to FIGS. 15 and 16, a second bank 45 is formed on the target substrate SUB, and light emitting elements 30 are placed on the first insulating layer 51 and each of the electrodes 21 and 22. The second bank 45 may surround an area in which the first banks 40 are disposed on the target substrate SUB. As described above, the second bank 45 may be disposed at each boundary between subpixels PXn and may separate an emission area EMA and a cutout area CBA of each subpixel PXn from each other.

Ends of each light emitting element 30 on the first insulating layer 51 may be placed on the first electrode 21 and the second electrode 22. The light emitting elements 30 dispersed in ink may be sprayed onto the target substrate SUB. In an embodiment, the light emitting elements 30 dispersed in ink may be prepared and sprayed onto the target substrate SUB through a printing process using an inkjet printing device. The ink sprayed through the inkjet printing device may be settled in the area surrounded by the second bank 45. The second bank 45 may prevent the ink from overflowing into other neighboring subpixels PXn.

In case that the ink including the light emitting elements 30 is sprayed, electrical signals are transmitted to the electrodes 21 and 22 to place the light emitting elements 30 on the first insulating layer 51. In case that the electric signals are transmitted to the electrodes 21 and 22, an electric field may be generated on the electrodes 21 and 22. The light emitting elements 30 dispersed in the ink may receive a dielectrophoretic force due to the electric field, and the dielectrophoretic force applied to the light emitting elements 30 may change the orientation direction and position of the light emitting elements 30, thereby settling the light emitting elements 30 on the first insulating layer 51. A length h of each light emitting element 30 may be greater than the distance between the first electrode 21 and the second electrode 22, and ends of each light emitting element 30 may be placed on the first electrode 21 and the second electrode 22. The distance between the first electrode 21 and the second electrode 22 may be the same as the width of the first insulating layer 51, and process dispersion may be small because the electrodes 21 and 22 are formed after the first insulating layer 51 is formed. Accordingly, ends of each light emitting element 30 placed on the first insulating layer 51 by the dielectrophoretic force can be accurately placed on the first electrode 21 and the second electrode 22, respectively, and an error in the degree of orientation or deflection between the light emitting elements 30 can be minimized.

A process of cutting a portion of each of the first electrode 21 and the second electrode 22 disposed in the cutout area CBA is performed. As described above with reference to FIG. 2, the first electrode 21 and the second electrode 22 extend in a direction, but may be partially separated from each other in the cutout area CBA. Electrical signals for aligning the light emitting elements 30 may be simultaneously transmitted to the electrodes 21 and 22 connected to the subpixels PXn. In case that the light emitting elements 30 are placed on the first insulating layer 51, a cutting process for separating each of the electrodes 21 and 22 for each subpixel PXn may be performed.

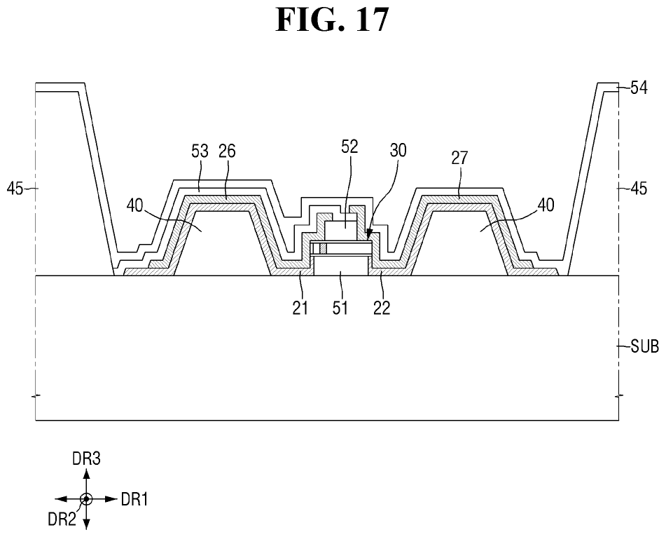

Referring to FIG. 17, a second insulating layer 52, a third insulating layer 53, a first contact electrode 26, a second contact electrode 27, and a fourth insulating layer 54 are formed on the light emitting elements 30. Their arrangement and shape are the same as those described above. Through the above process, the display device 10 including the light emitting elements 30 may be manufactured.

Other embodiments of the display device 10 will now be described with reference to other drawings.

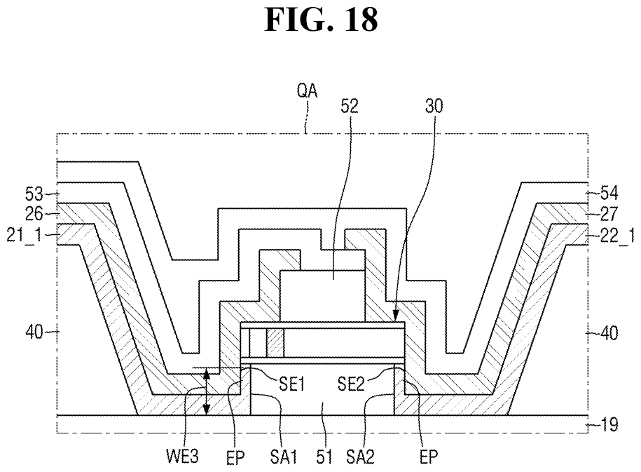

FIG. 18 is a schematic cross-sectional view of a portion of a display device according to another embodiment.

Referring to FIG. 18, in the display device 10 according to the embodiment, a thickness WE3 of a first portion EP of each of electrodes 21_1 and 22_1 may be smaller than a thickness of a first insulating layer 51. Ends of a light emitting element 30 may be disposed on the electrodes 21_1 and 22_1, but the first portion EP of each of the electrodes 21_1 and 22_1 may not contact the light emitting element 30.

As described above, a process of partially removing an electrode layer MTL may be performed through a wet etching process and a dry etching process. The electrode layer MTL remaining after an etching process may cause misalignment of the light emitting element 30 or a short circuit between the electrodes 21 and 22. To prevent this, an etching process for removing the electrode layer MTL may be performed as an over-etching process. A portion of the electrode layer MTL disposed on side surfaces of the first insulating layer 51 as well as a portion thereof disposed on the first insulating layer 51 may be removed to some extent. Accordingly, the thickness WE3 of the first portion EP of each of the electrodes 21_1 and 22_1 may be smaller than the thickness of the first insulating layer 51, and the first portions EP may not contact side surfaces of ends of the light emitting element 30. However, the light emitting element 30 may be horizontally disposed on the first insulating layer 51, and end surfaces of the light emitting element 30 may smoothly contact a first contact electrode 26 and a second contact electrode 27. The current embodiment is different from the embodiment of FIG. 4 in that the first portions EP of the first electrode 21_1 and the second electrode 22_1 do not contact ends of the light emitting element 30. Thus, any redundant description will be omitted below.

The first electrode 21 and the second electrode 22 may not extend in a direction. In some embodiments, each of the electrodes 21 and 22 of the display device 10 may include a portion extending with a varying width and a portion extending in a different direction from the above portion.

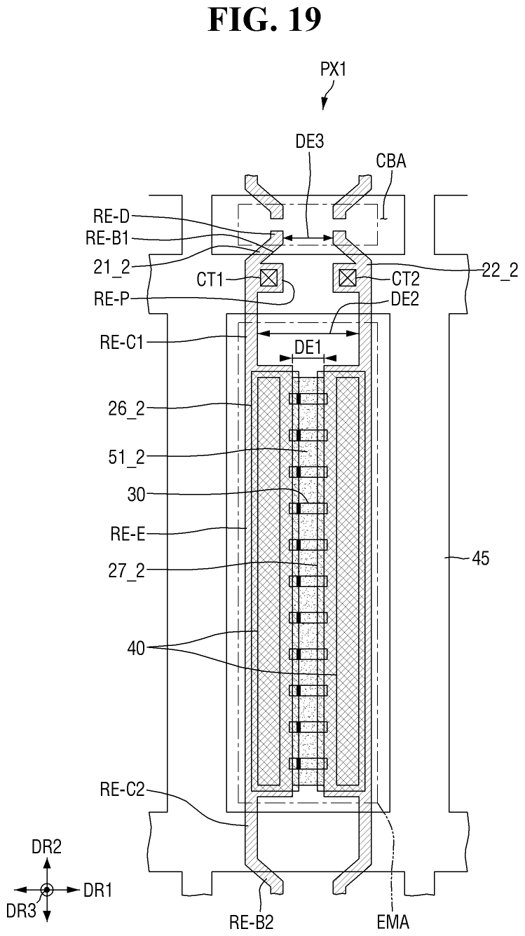

FIG. 19 is a schematic plan view of a subpixel of a display device according to another embodiment.

Referring to FIG. 19, electrodes 21_2 and 22_2 of the display device 10 according to the embodiment may each include a widened portion RE-E extending in the second direction DR2 and having a greater width than other portions, bent portions RE-B1 and RE-B2 extending in a direction inclined from the first direction DR1 and the second direction DR2, and connection portions RE-C1 and RE-C2 connecting (or extending between) the bent portions RE-B1 and RE-B2 and the widened portion RE-E. Each of the electrodes 21_2 and 22_2 may generally extend in the second direction DR2, but may have a greater width in a portion thereof or may be bent in a direction inclined from the second direction DR2. A first electrode 21_2 and a second electrode 22_2 may be disposed in a symmetrical structure with respect to a first insulating layer 51 disposed between them. The following description will focus on the shape of the first electrode 21_2.

The first electrode 21_2 may include the widened portion RE-E having a greater width than other portions. The widened portion RE-E may be disposed on each first bank 40 in an emission area EMA of each subpixel PXn and may extend in the second direction DR2. A first insulating layer 51_2 may be disposed between the widened portions RE-E of the first electrode 21_2 and the second electrode 22_2, and light emitting elements 30 may be disposed on the first insulating layer 512. The first insulating layer 51_2 may contact the respective widened portions RE-E of the electrodes 21_2 and 22_2. A first contact electrode 26_2 and a second contact electrode 27_2 may be disposed on the widened portions RE-E of the electrodes 21_2 and 22_2, respectively, and widths of the first contact electrode 26_2 and the second contact electrode 27_2 may be smaller than widths of the widened portions RE-E. This is the same as described above.

The connection portions RE-C1 and RE-C2 may be respectively connected to sides of each of the widened portions RE-E in the second direction DR2. A first connection portion RE-C1 is disposed on a side of each widened portion RE-E in the second direction DR2, and a second connection portion RE-C2 is disposed on another side of each widened portion RE-E. The connection portions RE-C1 and RE-C2 may be connected to each widened portion RE-E and may be disposed across the emission area EMA of each subpixel PXn and a second bank 45.

Widths of the first connection portion RE-C1 and the second connection portion RE-C2 may be smaller than the width of each widened portion RE-E. A side of each of the connection portions RE-C1 and RE-C2 extending in the second direction DR2 may be collinearly connected to a side of each widened portion RE-E extending in the second direction DR2. For example, among sides of the widened portions RE-E and sides of the connection portions RE-C1 and RE-C2, sides positioned outside a center of the emission area EMA may be connected to each other. Accordingly, a distance DE1 between the widened portions RE-E of the first electrode 21_2 and the second electrode 22_2 may be smaller than a distance DE2 between the connection portions RE-C1 and RE-C2.

The bent portions RE-B1 and RE-B2 are connected to the connection portions RE-C1 and RE-C2. The bent portions RE-B1 and RE-B2 may include a first bent portion RE-B1 connected to the first connection portion RE-C1 and disposed across the second bank 45 and a cutout area CBA and a second bent portion RE-B2 connected to the second connection portion RE-C2 and disposed across the second bank 45 and the cutout area CBA of another subpixel PXn. The bent portions RE-B1 and RE-B2 connected to the connection portions RE-C1 and RE-C2 may be bent in a direction inclined from the second direction DR2, for example, toward a center of each subpixel PXn. Accordingly, a shortest distance DE3 between the bent portions RE-B1 and RE-B2 of the first electrode 21_2 and the second electrode 222 may be smaller than the distance DE2 between the connection portions RE-C1 and RE-C2. However, the shortest distance DE3 between the bent portions RE-B1 and RE-B2 may be greater than the distance DE1 between the widened portions RE-E.

A relatively wide contact portion RE-P may be formed at each portion where the first connection portion RE-C1 and the first bent portion RE-B1 are connected. The contact portions RE-P may overlap the second bank 45, and a first contact hole CT1 and a second contact hole CT2 of the first electrode 21_2 and the second electrode 22_2 may be formed in the contact portions RE-P.

Fragment portions RE-D remaining after the first electrode 21_2 and the second electrode 22_2 are separated in the cutout area CBA may be formed at ends of the first bent portions RE-B1. The fragment portions RE-D may be portions remaining after the electrodes 21_2 and 22_2 of a subpixel PXn neighboring another subpixel PXn in the second direction DR2 are cut in the cutout area CBA.

The embodiment of FIG. 19 is different from the embodiment of FIG. 2 in that the first electrode 21_2 and the second electrode 22_2 each include the widened portion RE-E, the connection portions RE-C1 and RE-C2, and the bent portions RE-B1 and RE-B2 and are symmetrically disposed with respect to the center of each subpixel PXn. However, the disclosure is not limited thereto. In some embodiments, the first electrode 21_2 and the second electrode 22_2 may have different shapes.

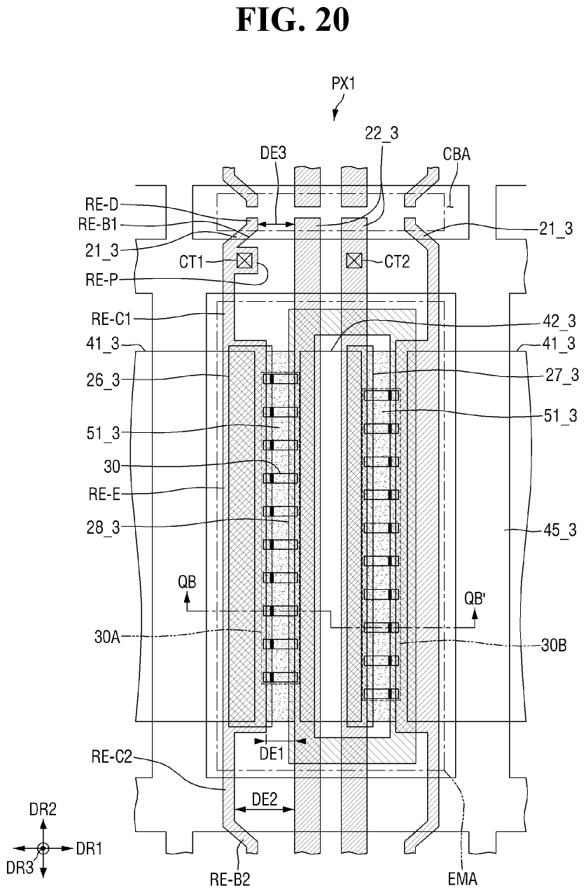

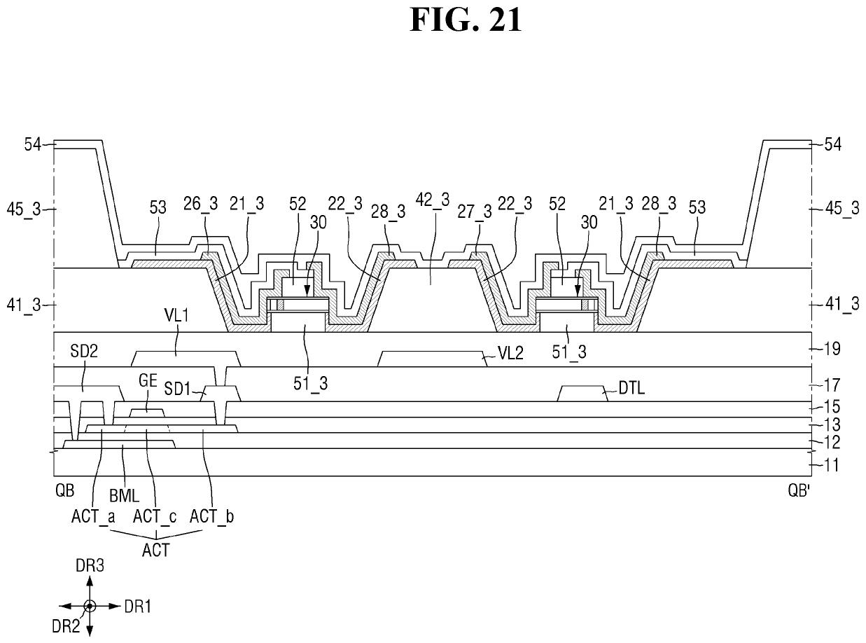

FIG. 20 is a schematic plan view of a subpixel of a display device according to another embodiment. FIG. 21 is a schematic cross-sectional view taken along line QB-QB′ of FIG. 20.

Referring to FIGS. 20 and 21, the display device 10 may include first electrodes 21_3 and second electrodes 22_3 in each subpixel PXn. The first electrodes 21_3 may have the same shape as that of the embodiment of FIG. 19. First electrodes 21_3, for example, two first electrodes 21_3, may be symmetrically disposed with respect to a center of each subpixel PXn. The second electrodes 223 may have the same shape as that of the embodiment of FIG. 2. Second electrodes 22_3, for example, two second electrodes 22_3, may be disposed between the first electrodes 21_3. A distance between the first and second electrodes 21_3 and 22_3 may vary according to a portion of the first electrode 21_3. For example, a distance DE1 between a widened portion RE-E and a second electrode 22_3 may be smaller than a distance DE2 between connection portions RE-C1 and RE-C2 and the second electrode 22_3 and a distance DE3 between bent portions RE-B1 and RE-B2 and the second electrode 22_3. The distance DE2 between the connection portions RE-C1 and RE-C2 and the second electrode 22_3 may be greater than the distance DE3 between the bent portions RE-B1 and RE-B2 and the second electrode 22_3. However, the disclosure is not limited thereto. Since the shapes of the electrodes 21_3 and 22_3 are the same as those described above with reference to FIGS. 2 and 19, a detailed description thereof will be omitted.

The arrangement and shape of first banks 40 (41_3 and 42_3), a first insulating layer 51_3, and contact electrodes 26_3, 27_3, and 28_3 disposed in each subpixel PXn may vary according to the arrangement of the first electrodes 21_3 and the second electrodes 22_3.

The first insulating layer 51_3 may be disposed between the widened portion RE-E of each first electrode 21_3 and a second electrode 22_3, and side surfaces of the first insulating layer 51_3 may contact the widened portion RE-E of each first electrode 21-3 and the second electrode 22_3, respectively. Light emitting elements 30 may have an end disposed on the widened portion RE-E of the first electrode 21_3 and another end disposed on the second electrode 22_3.

The first banks 40 may include first sub-banks 41_3 and a second sub-bank 42_3 having different widths. The first sub-banks 41_3 and the second sub-bank 42_3 may each extend in the second direction DR2, but may have different widths measured in the first direction DR1. Since the first sub-banks 41_3 have a greater width than the second sub-bank 42_3, each of the first sub-banks 41_3 may be disposed across a boundary with a subpixel PXn neighboring another subpixel PXn in the first direction DR1. For example, the first sub-banks 41_3 may be disposed in an emission area EMA of each subpixel PXn and at boundaries between the subpixels PXn. Accordingly, a portion of a second bank 45_3 which extends in the second direction DR2 may be partially disposed on each first sub-bank 41_3. Two first sub-banks 413 may be partially disposed in a subpixel PXn. A second sub-bank 42_3 may be disposed between the first sub-banks 41_3.

The second sub-bank 423 may extend in the second direction DR2 in a center of the emission area EMA of each subpixel PXn. The second sub-bank 42_3 may have a smaller width than the first sub-banks 41_3 and may be disposed between the first sub-banks 41_3 and spaced apart from the first sub-banks 41_3.

The widened portions RE-E of the first electrodes 21_3 and the second bank 45_4 may be disposed on the first sub-banks 41_3. The widened portions RE-E of the first electrodes 21_3 of subpixels PXn neighboring each other in the first direction DR1 may be disposed on a first sub-bank 41_3. For example, the widened portions RE-E of two first electrodes 21_3 are disposed on a first sub-bank 41_3. Two second electrodes 223 may be disposed on the second sub-bank 42_3. The second electrodes 22_3 may be disposed on sides of the second sub-bank 42_3 extending in the second direction DR2 and may be spaced apart from each other on the second sub-bank 42_3.

Any one of the first electrodes 213 may include a contact portion RE-P to form a first contact hole CT1, and the other first electrode 21_3 may not include the contact portion RE-P. Similarly, any one of the second electrodes 22_3 may include a contact portion RE-P to form a second contact hole CT2, and the other second electrode 22_3 may not include the contact portion RE-P. Electrodes 21_3 and 22_3 connected to a first transistor TR1 or a second voltage wiring VL2 through the contact hole CT1 or CT2 may receive electrical signals from them, and the other electrodes 21_3 and 22_3 may receive electrical signals through the contact electrodes 26_3, 27_3, and 28_3 which will be described below.

Ends of each light emitting element 30 on the first insulating layer 513 are disposed on the widened portion RE-E of a first electrode 21_3 and a second electrode 22_3. Among the ends of each light emitting element 30, an end at which a second semiconductor layer 32 is disposed may be disposed on a first electrode 21_3. Accordingly, an end of each first light emitting element 30A between the electrodes 21_3 and 22_3 disposed on a left side of the center of each subpixel PXn and an end of each second light emitting element 30B between the electrodes 21_3 and 22_3 disposed on a right side of the center of each subpixel PXn may face in opposite directions.

The display device 10 including a greater number of the electrodes 21_3 and 22_3 may include a greater number of the contact electrodes 26_3, 27_3, and 28_3.

In an embodiment, the contact electrodes 26_3, 27_3, and 283 may include a first contact electrode 26_3 disposed on any one of the first electrodes 21_3, a second contact electrode 27_3 disposed on any one of the second electrodes 22_3, and a third contact electrode 283 disposed on the other first electrode 21_3 and the other second electrode 22_3 and surrounding the second contact electrode 27_3.

The first contact electrode 26_3 is disposed on any one of the first electrodes 21_3. For example, the first contact electrode 26_3 is disposed on the widened portion RE-E of the first electrode 21_3 on which an end of each first light emitting element 30A is disposed. The first contact electrode 26_3 may contact the widened portion RE-E of the first electrode 21_3 and an end of each first light emitting element 30A. The second contact electrode 27_3 is disposed on any one of the second electrodes 22_3. For example, the second contact electrode 27_3 is disposed on the second electrode 22_3 on which another end of each second light emitting element 30B is disposed. The second contact electrode 27_3 may contact the second electrode 22_3 and the another end of each second light emitting element 30B. The first contact electrode 26_3 and the second contact electrode 27_3 may respectively contact the electrodes 21_3 and 22_3 in which the first contact hole CT1 and the second contact hole CT2 are formed. The first contact electrode 263 may contact the first electrode 21_3 electrically connected to the first transistor TR1 through the first contact hole CT1, and the second contact electrode 27_3 may contact the second electrode 22_3 electrically connected to the second voltage wiring VL2 through the second contact hole CT2. The first contact electrode 26_3 and the second contact electrode 27_3 may transfer an electrical signal, received from the first transistor TR1 or the second voltage wiring VL2, to the light emitting elements 30. The first contact electrode 26_3 and the second contact electrode 27_3 are substantially the same as those described above.

Electrodes 21_3 and 22_3 in which the contact holes CT1 and CT2 are not formed are further disposed in each subpixel PXn. The electrodes 21_3 and 22_3 may be substantially in a floating state because they do not receive an electric signal directly from the first transistor TR1 or the second voltage wiring VL2. However, the third contact electrode 28_3 may be disposed on the electrodes 21_3 and 22_3 in which the contact holes CT1 and CT2 are not formed, and an electrical signal transmitted to the light emitting elements 30 may flow through the third contact electrode 28_3.

The third contact electrode 28_3 may be disposed on the first electrode 21_3 and the second electrode 22_3 in which the contact holes CT1 and CT2 are not formed, and may surround the second contact electrode 27_3. The third contact electrode 28_3 may include portions extending in the second direction DR2 and portions connecting them and extending in the first direction DR1 to surround the second contact electrode 27_3. The portions of the third contact electrode 28_3 which extend in the second direction DR2 may be respectively disposed on the first electrode 21_3 and the second electrode 22_3 in which the contact holes CT1 and CT2 are not formed, and may contact the light emitting elements 30. For example, a portion of the third contact electrode 28_3 which is disposed on the second electrode 22_3 may contact another end of each first light emitting element 30A, and a portion thereof disposed on the first electrode 21_3 may contact an end of each second light emitting element 30B. The portions of the third contact electrode 28_3 which extend in the first direction DR1 may overlap the second electrode 22_3 in which the second contact hole CT2 is formed, but another insulating layer (not illustrated) may be disposed between them so that they are not directly connected to each other.

An electrical signal transmitted from the first contact electrode 26_3 to an end of each first light emitting element 30A is transferred to the third contact electrode 28_3 contacting another end of each first light emitting element 30A. The third contact electrode 28_3 may transmit the electrical signal to an end of each second light emitting element 30B, and the electrical signal may be transferred to the second electrode 22_3 through the second contact electrode 27_3. Accordingly, electrical signals for light emission of the light emitting elements 30 may be transmitted to only a first electrode 21_3 and a second electrode 22_3, and the first light emitting elements 30A and the second light emitting elements 30B may be connected in series through the third contact electrode 28_3.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a first electrode and a second electrode spaced apart from each other on a substrate;
a first insulating layer disposed between the first electrode and the second electrode and not overlapping the first electrode and the second electrode in a thickness direction of the first insulating layer; and
a light emitting element disposed on the first insulating layer,
wherein side surfaces of the first insulating layer contact the first electrode and the second electrode.

2. The display device of claim 1, wherein a first portion of each of the first electrode and the second electrode which contact the side surfaces of the first insulating layer respectively contact the side surfaces of the first insulating layer in the thickness direction of the first insulating layer.

3. The display device of claim 2, wherein a thickness of the first insulating layer is greater than a maximum thickness of each of the first electrode and the second electrode.

4. The display device of claim 2, wherein a width of the first portion of each of the first electrode and the second electrode is smaller than a thickness of portions other than the first portion.

5. The display device of claim 2, wherein
an upper surface of the first portion of each of the first and second electrodes and an upper surface of the first insulating layer lie in a same plane, and
respective ends of the light emitting element electrically contact the first portion of each of the first electrode and the second electrode.

6. The display device of claim 2, wherein a height of a contact surface between each of the first electrode and the second electrode and a side surface of the first insulating layer is greater than a thickness of each of the first electrode and the second electrode.

7. The display device of claim 1, wherein
the light emitting element extends in a direction, and
a length of the light emitting element is greater than a width of the first insulating layer.

8. The display device of claim 7, wherein
an end of the light emitting element is disposed on the first electrode, and
another end of the light emitting element is disposed on the second electrode.

9. The display device of claim 7, further comprising
a second insulating layer including at least a portion disposed on the light emitting element,
wherein a width of the second insulating layer is smaller than the width of the first insulating layer.

10. The display device of claim 9, further comprising:
a first contact electrode disposed on the first electrode and electrically contacting an end of the light emitting element; and
a second contact electrode disposed on the second electrode and electrically contacting another end of the light emitting element.

11. The display device of claim 9, further comprising:
banks disposed between the substrate and the first electrode and between the substrate and the second electrode,
wherein the first insulating layer does not contact the banks.

12. A display device comprising:
a first electrode disposed on a substrate and extending in a first direction;
a second electrode spaced apart from the first electrode in a second direction and extending in the first direction;
an insulating layer disposed between the first electrode and the second electrode and extending in the first direction; and
light emitting elements disposed on the insulating layer and arranged in the first direction, wherein
side surfaces of the insulating layer contact the first electrode and the second electrode, and
an end of each of the light emitting elements is disposed on the first electrode, and another end of each of the light emitting elements is disposed on the second electrode.

13. The display device of claim 12, further comprising:
a first contact electrode disposed on the first electrode and electrically contacting the end of each of the light emitting elements; and
a second contact electrode disposed on the second electrode and electrically contacting the another end of each of the light emitting elements,
wherein at least a portion of each of the first contact electrode and the second contact electrode overlaps the insulating layer in a thickness direction of the insulating layer.

14. The display device of claim 12, wherein
the first electrode comprises:
a bent portion extending in the second direction different from the first direction;
a widened portion extending in the first direction and having a greater width than the bent portion; and
a connection portion extending between the bent portion and the widened portion and extending in the first direction, and
the insulating layer is disposed between the widened portion of the first electrode and the second electrode so that a side surface of the insulating layer contacts the widened portion of the first electrode.

15. The display device of claim 14, wherein
the second electrode has a symmetrical structure to the first electrode with respect to the insulating layer, and
another side surface of the insulating layer contacts a widened portion of the second electrode.

16. The display device of claim 15, wherein
a distance between the widened portion of the first electrode and the widened portion of the second electrode is smaller than a distance between the connection portion portion of the first electrode and a connection portion of the second electrode, and
a shortest distance between the bent portion the first electrode and a bent portion of the second electrode is greater than the distance between the widened portion of the first electrode and the widened portion of the second electrode and smaller than the distance between the connection portion of the first electrode and the connection portion of the second electrode.

17. A method of manufacturing a display device, the method comprising:
forming an insulating layer on a substrate and forming an electrode layer covering the substrate and the insulating layer;
forming a first electrode and a second electrode spaced apart from each other by the insulating layer by partially removing the electrode layer to expose an upper surface of the insulating layer; and
placing light emitting elements on the insulating layer.

18. The method of claim 17, wherein the removing of the electrode layer comprises a first etching process performed as a wet etching process and a second etching process performed as a dry etching process after the first etching process.

19. The method of claim 18, comprising
forming banks spaced apart from each other on the substrate before the forming of the insulating layer.

20. The method of claim 19, wherein
the forming of the electrode layer comprises forming the electrode layer to cover the banks and the insulating layer, and
the forming of the first electrode and the second electrode comprises disposing the first and second electrodes on the banks and directly disposing at least a portion of each of the first electrode and the second electrode on the substrate.
